(19) United States
(12) Patent Application Publication
(10) Pub. No.: US 2026/0089971 A1
(43) Pub. Date: Mar. 26, 2026

(54) SEMICONDUCTOR MEMORY DEVICE AND METHOD OF FABRICATING THE SAME

(71) Applicant: Samsung Electronics Co., Ltd., Suwon-si (KR)

(72) Inventor: Jeon Il LEE, Suwon-si (KR)

(73) Assignee: Samsung Electronics Co., Ltd., Suwon-si (KR)

(21) Appl. No.: 19/052,837

(22) Filed: Feb. 13, 2025

(30) Foreign Application Priority Data
Sep. 23, 2024 (KR) 10-2024-0128430

(51) Int. Cl. H10B 53/20; H10B 53/30; H10B 53/40

(52) U.S. Cl. CPC H10B 53/20; H10B 53/30; H10B 53/40

(57) ABSTRACT

Disclosed are semiconductor memory devices and their fabrication methods. The semiconductor memory device comprises a first substrate, a cell stack on the first substrate and comprising a plurality of plate lines and a plurality of stack insulation layers that are alternately stacked, an electrode plug that penetrates the cell stack; a dielectric layer between the electrode plug and the cell stack, a selection transistor on the cell stack and connected to the electrode plug, an upper insulation layer that covers the selection transistor and the cell stack, and a peripheral circuit structure on the upper insulation layer and connected to the selection transistor. The dielectric layer comprises at least one selected from a ferroelectric material and an antiferroelectric material.

### CROSS-REFERENCE TO RELATED APPLICATION

This application claims priority under 35 U.S.C § 119 to Korean Patent Application No. 10-2024-0128430 filed on Sep. 23, 2024 in the Korean Intellectual Property Office, the disclosure of which is hereby incorporated by reference in its entirety.

### BACKGROUND

The present inventive concepts relate to a semiconductor memory device and a method of fabricating the same.

Semiconductor devices have an important role in the electronic industry because of their small size, multi-functionality, and/or low fabrication cost. However, the semiconductor devices are being highly integrated with the remarkable development of the electronic industry. Line widths of patterns of semiconductor devices are being reduced for high integration thereof. However, new exposure techniques and/or expensive exposure techniques are required for fineness of the patterns such that it is difficult to highly integrate semiconductor devices. Various studies have thus recently been conducted for new integration techniques.

### SUMMARY

Some embodiments of the present inventive concepts provide a semiconductor memory device whose operating speed is improved.

Some embodiments of the present inventive concepts provide a method of fabricating the semiconductor memory device.

According to some embodiments of the present inventive concepts, a semiconductor memory device may comprise: a first substrate; a cell stack on the first substrate, wherein the cell stack comprises a plurality of plate lines and a plurality of stack insulation layers that are alternately stacked; an electrode plug that penetrates the cell stack; a dielectric layer between the electrode plug and the cell stack; a selection transistor on the cell stack and connected to the electrode plug; an upper insulation layer that covers the selection transistor and the cell stack; and a peripheral circuit structure on the upper insulation layer and connected to the selection transistor. The dielectric layer may comprise at least one selected from a ferroelectric material and an antiferroelectric material.

According to some embodiments of the present inventive concepts, a semiconductor memory device may comprise: a first substrate; a cell stack on the first substrate, wherein the cell stack comprises a plurality of plate lines and a plurality of stack insulation layers that are alternately stacked; a plurality of electrode plugs that penetrate the cell stack; a plurality of dielectric layers between the electrode plugs and the cell stack; a plurality of active patterns on the cell stack; a plurality of word lines that are correspondingly adjacent to the active patterns and extend in a first direction parallel to a top surface of the first substrate; a first upper insulation layer that covers the cell stack and the word lines; a plurality of bit lines on the first upper insulation layer and intersecting the first direction; a second upper insulation layer that covers the bit lines and the first upper insulation layer; a second substrate on the second upper insulation layer; a plurality of peripheral circuit transistors having gate structures disposed on one surface of the second substrate; and a bit-line connection contact plug that connects one of the bit lines to one of the peripheral circuit transistors. A vertical length of the bit-line connection contact plug may be less than a vertical length of one of the electrode plugs.

According to some embodiments of the present inventive concepts, a semiconductor memory device may comprise: a first substrate that comprises a cell array region and a connection region; a cell stack on the first substrate, wherein the cell stack comprises a plurality of plate lines and a plurality of stack insulation layers that are alternately stacked, an end portion of the cell stack constituting a stepwise shape in the connection region; a plurality of electrode plugs that penetrate the cell stack in the cell array region; a plurality of dielectric layers between the electrode plugs and the cell stack; a plurality of active patterns on the cell stack; a plurality of selection transistors on the active patterns; a plurality of word lines that have connection with gates of the selection transistors and extend in a first direction parallel to a top surface of the first substrate; a first upper insulation layer that covers the cell stack and the word lines; a plurality of bit lines on the first upper insulation layer and intersecting the first direction; a planarized insulation layer that covers the end portion of the cell stack on the connection region; a second upper insulation layer that covers the bit lines, the first upper insulation layer, and the planarized insulation layer; a second substrate on the second upper insulation layer; a plurality of peripheral circuit transistors on one surface of the second substrate; a bit-line connection contact plug that connects one of the bit lines to one of the peripheral circuit transistors; and a plurality of plate connection contact plugs in contact with the plate lines on the connection region. The dielectric layer may comprise at least one selected from a ferroelectric material and an antiferroelectric material.

According to some embodiments of the present inventive concepts, a method of fabricating a semiconductor memory device may comprise: alternately stacking on a first substrate a plurality of first sacrificial layers and a plurality of second sacrificial layers to form a preliminary stack; forming a selection transistor on the preliminary stack; forming an electrode plug and a dielectric layer that penetrate the preliminary stack; replacing the first sacrificial layers with a plurality of stack insulation layers; replacing the second sacrificial layers with a plurality of plate lines to form a cell stack including the plurality of plate lines and the plurality of stack insulation layers; forming a plurality of bit lines on the cell stack; and forming a peripheral circuit structure on the bit lines.

According to some embodiments of the present inventive concepts, a method of fabricating a semiconductor memory device may comprise: sequentially stacking a first semiconductor layer and a second semiconductor layer on a sacrificial substrate; alternately stacking on the second semiconductor layer a plurality of first sacrificial layers and a plurality of second sacrificial layers to form a preliminary stack; forming an electrode plug and a dielectric layer that penetrate the preliminary stack; replacing the first sacrificial layers with a plurality of stack insulation layers; replacing the second sacrificial layers with a plurality of plate lines to form a cell stack including the plurality of plate lines and the plurality of stack insulation layers; bonding a first substrate onto the cell stack; removing the sacrificial substrate and the first semiconductor layer; patterning the second semiconductor layer to form an active pattern; forming a word line that surrounds a lateral surface of the active pattern; forming a bit line in contact with an end portion of the active pattern; forming an upper insulation layer that covers the bit line; and forming a peripheral circuit structure on the upper insulation layer.

### BRIEF DESCRIPTION OF DRAWINGS

FIG. 1 illustrates a block diagram showing a semiconductor memory device according to some embodiments of the present inventive concepts.

FIG. 2 illustrates a plan view showing a semiconductor memory device according to some embodiments of the present inventive concepts.

FIG. 3A illustrates a cross-sectional view taken along line A-A′ of FIG. 2.

FIG. 3B illustrates a cross-sectional view taken along line B-B′ of FIG. 2.

FIG. 4A illustrates a cross-sectional view taken along line A-A′ of FIG. 2.

FIG. 4B illustrates a cross-sectional view taken along line B-B′ of FIG. 2.

FIG. 5 illustrates a cross-sectional view taken along line B-B′ of FIG. 2.

FIG. 6 illustrates a cross-sectional view taken along line B-B′ of FIG. 2.

FIGS. 7A to 7L illustrate plan views showing a method of fabricating a semiconductor memory device whose plan view is depicted in FIG. 2.

FIGS. 8A to 8M illustrate cross-sectional views showing a method of fabricating a semiconductor memory device whose cross-section is depicted in FIG. 3A.

FIGS. 9A to 9C illustrate cross-sectional views showing a method of fabricating a semiconductor memory device whose cross-section is depicted in FIG. 3B.

FIG. 10 illustrates a plan view showing a semiconductor memory device according to some embodiments of the present inventive concepts.

FIG. 11A illustrates a cross-sectional view taken along line A-A′ of FIG. 10.

FIG. 11B illustrates a cross-sectional view taken along line C-C′ of FIG. 10.

FIG. 12A illustrates a cross-sectional view taken along line A-A′ of FIG. 10.

FIG. 12B illustrates a cross-sectional view taken along line C-C′ of FIG. 10.

FIGS. 13A to 13G illustrate plan views showing a method of fabricating a semiconductor memory device whose plan view is depicted in FIG. 10.

FIGS. 14A to 14I illustrate cross-sectional views showing a method of fabricating a semiconductor memory device whose cross-section is depicted in FIG. 11A.

FIGS. 15A to 15C illustrate cross-sectional views showing a method of fabricating a semiconductor memory device whose cross-section is depicted in FIG. 11B.

### DETAILED DESCRIPTION OF EMBODIMENTS

Some embodiments of the present inventive concepts will now be described in detail with reference to the accompanying drawings to aid in clearly explaining the present inventive concepts. In this description, the term “word line” may be called “first conductive line”, the term “bit line” may be called “second conductive line”, and the term “plate line” may be called “third conductive line.” In this description, such terms as “first” and “second” may be used to simply distinguish identical or similar components from each other, and the sequence of such terms may be changed in accordance with the order of mention.

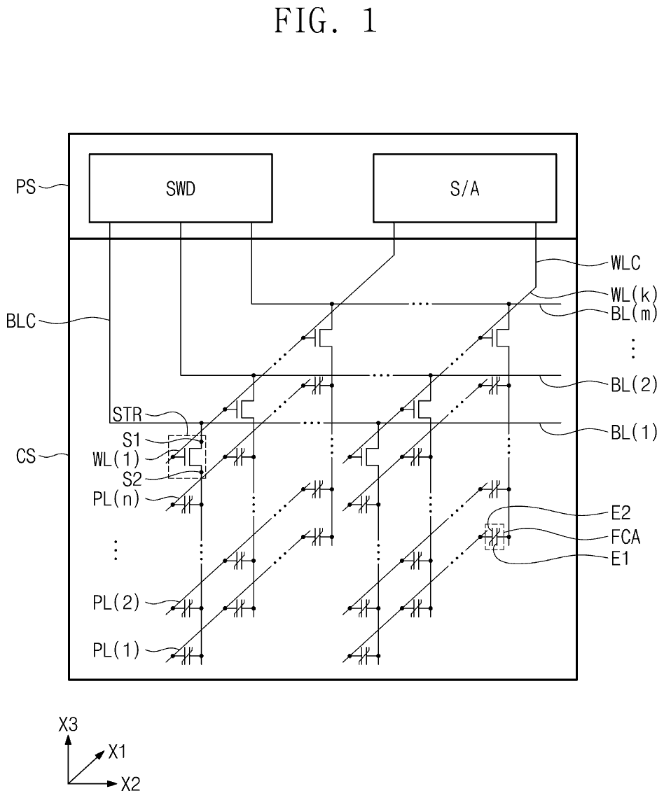

FIG. 1 illustrates a block diagram showing a semiconductor memory device according to some embodiments of the present inventive concepts.

Referring to FIG. 1, a semiconductor memory device according to the present embodiment may include a cell structure CS and a peripheral circuit structure PS disposed on the cell structure CS. The cell structure CS may include word lines WL(1) to WL(k), bit lines BL(1) to BL(m), plate lines PL(2) to PL(n), selection transistors STR, and capacitors FCA. The k numbers of word lines WL may extend in a first direction X1. The word lines WL may be spaced apart from each other along a second direction X2 intersecting the first direction X1. The m numbers of bit lines BL may extend along the second direction X2 and may be spaced apart from each other along the first direction X1. The word lines WL and the bit lines BL may be positioned on an upper portion of the cell structure CS.

The selection transistors STR may be correspondingly disposed at intersections where the word lines WL and the bit lines BL intersect each other. The selection transistors STR may be two-dimensionally arranged along the first direction X1 and the second direction X2. A gate of one selection transistor STR may be a portion of the word line WL connected thereto. A first terminal S1 of the one selection transistor STR may be connected to one of the bit lines BL.

A second terminal S2 of each of the selection transistors STR may be connected to a plurality of capacitors FCA (e.g., n numbers of capacitors FCA). The capacitors FCA connected to one selection transistor STR may be arranged side by side along the third direction X3. In the cell structure CS, the capacitors FCA may be three-dimensionally arranged along the first, second, and third directions X1, X2, and X3. Each of the capacitors FCA may include a first electrode E1, a second electrode E2, and a dielectric layer interposed between the first electrode E1 and the second electrode E2. The capacitors FCA may each have a single-layered or multi-layered structure of at least one selected from a ferroelectric material and an antiferroelectric material as the dielectric layer. For example, the capacitors FCA may be ferroelectric capacitors, and in this case, the semiconductor memory device may be a ferroelectric random access memory (FeRAM). In an embodiment, the capacitors FCA may include a dielectric material (e.g., silicon oxide or aluminum oxide), as the dielectric layer, which does not exhibit ferroelectricity or antiferroelectricity, and in this case, the semiconductor memory device may be a dynamic random access memory (DRAM).

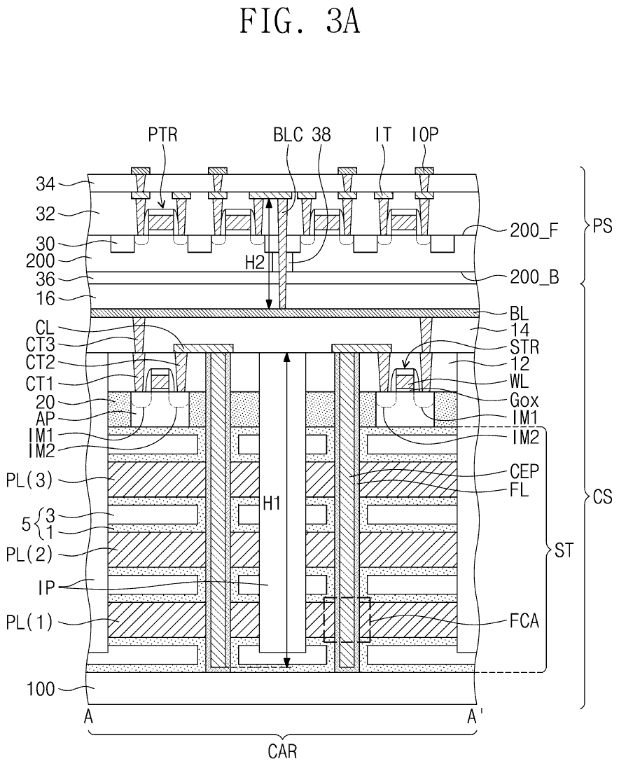

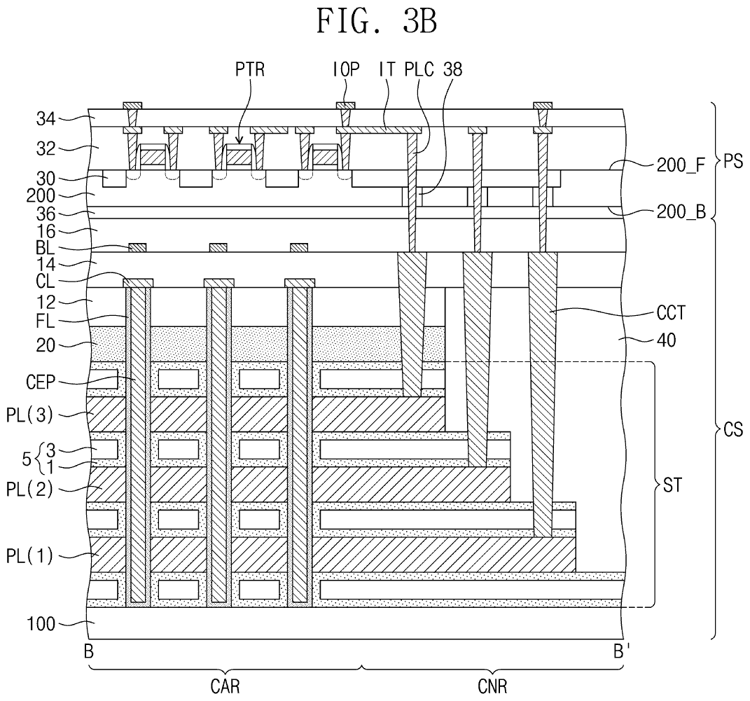

The first electrodes E1 of the capacitors FCA connected to one selection transistor STR may be connected to the first terminal S1 of the one selection transistor STR. The first electrodes E1 of the capacitors FCA may be connected to electrode plugs (see CEP of FIG. 3A) or may correspond to portions of the electrode plugs CEP. The second electrodes E2 of the capacitors FCA may be connected to the plate lines PL. The plate lines PL may each have a linear shape that extend along the first direction X1. The plate lines PL may be spaced apart from each other in the second direction X2 and the third direction X3. N numbers of plate lines PL may be stacked on each other. The k, m, and n may each be any natural number equal to or greater than 2.

Voltages applied to the plate lines PL and the electrode plugs CEP may be adjusted to control polarization direction of ferroelectric layers of the capacitors FCA. This principle may be used to write data to and read data from the capacitors FCA.

The peripheral circuit structure PS may include peripheral circuits connected to the word lines WL, the bit lines BL, and the plate lines PL of the cell structure CS. The peripheral circuits may include a sub-word line driver SWD, a sense amplifier S/A, a row decoder, a column decoder, and a control logic. The sub-word line driver SWD may be connected through word-line connection contact plugs WLC to the word lines WL. The sense amplifier S/A may be connected through bit-line connection contact plugs BLC to the bit lines BL.

The row decoder may decode a refresh address signal or a row address signal that is input from outside. In response to the row address signal or the refresh address signal, the sub-word line driver SWD may serve to select a specific word line WL.

In response to an address that is decoded from the column decoder, the sense amplifier S/A may detect and amplify a voltage difference between a selected bit line BL and a reference bit line, and may then output the amplified voltage difference.

The column decoder may provide a data delivery path between the sense amplifier S/A and an external device (e.g., a memory controller). The column decoder may decode a column address signal that is input from outside to select one of the bit lines BL.

The control logic may generate control signals that control operations to write data to the capacitors FCA of the cell structure CS and/or to read data from the capacitors FCA of the cell structure CS.

In the cell structure CS of the semiconductor memory device according to the present inventive concepts, as the word lines WL, the bit lines BL, and the selection transistors STR are positioned near the peripheral circuit structure PS (e.g., positioned on an upper portion of the cell structure CS), it may be possible to reduce vertical lengths of the word-line connection contact plugs WLC and the bit-line connection contact plugs BLC. There may thus be reduced electrical pathways between the sub-word line driver SWD of the peripheral circuit structure PS and the word lines WL of the cell structure CS, and between the sense amplifier S/A of the peripheral circuit structure PS and the bit lines BL of the cell structures CS, which may result in an improvement in operating speed.

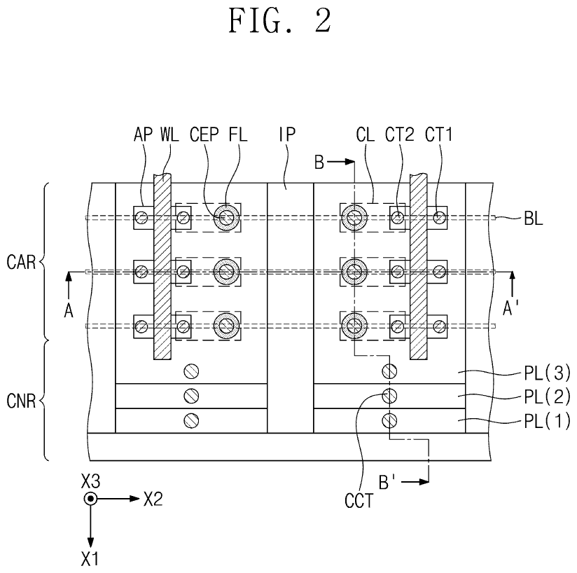

FIG. 2 illustrates a plan view showing a semiconductor memory device according to some embodiments of the present inventive concepts. FIG. 3A illustrates a cross-sectional view taken along line A-A′ of FIG. 2. FIG. 3B illustrates a cross-sectional view taken along line B-B′ of FIG. 2.

Referring to FIGS. 2, 3A, and 3B, a semiconductor memory device according to the present embodiment may include a cell structure CS and a peripheral circuit structure PS disposed on the cell structure CS. The cell structure CS may include a first substrate 100, a cell stack ST, selection transistors STR, word lines WL, bit lines BL, plate lines PL, and capacitors FCA. For example, the first substrate 100 may be a semiconductor substrate formed of a semiconductor material such as single-crystalline silicon, a dielectric substrate formed of dielectric material, or a silicon-on-insulator (SOI) substrate. The first substrate 100 may include a cell array region CAR and a connection region CNR that are disposed side by side along a first direction X1.

The cell stack ST may be disposed on the first substrate 100. The cell stack ST may include the plate lines PL and stack insulation layers 5 that are repeatedly and alternately stacked. The plate lines PL may be formed of a conductive material, such as tungsten. FIGS. 3A and 3B depicts three-layered plate lines PL(1) to PL(3), but the number of the plate lines PL is not limited thereto and may be four or more. Each of the stack insulation layers 5 may include a first insulation layer 1 and a second insulation layer 3. The first insulation layer 1 may have an etch selectivity with respect to the second insulation layer 3. The first insulation layer 1 may include a different material from that of the second insulation layer 3. For example, the first insulation layer 1 may be formed of silicon nitride, and the second insulation layer 3 may be formed of silicon oxide. The first insulation layer 1 may be in contact with the plate lines PL, and the second insulation layer 3 may be spaced apart from the plate lines PL. The stack insulation layer 5 may be positioned at each of top and bottom ends of the cell stack ST.

Active patterns AP may be disposed on the cell stack ST. When viewed in plan, the active patterns AP may each have a tetragonal or oval shape, and may be two-dimensionally arranged along the first direction X1 and a second direction X2. The active patterns AP may be formed of a semiconductor material, for example, single-crystalline silicon or polycrystalline silicon. The active patterns AP may be doped with impurities (or dopants) of a first conductivity type. The first conductivity type may be n-type or p-type. The active patterns AP may be spaced apart from each other. A first device isolation pattern 20 may fill a space between the active patterns AP. The first device isolation pattern 20 may be formed of a dielectric material, such as silicon oxide, silicon nitride, or silicon oxynitride.

The selection transistors STR may be correspondingly disposed on the active patterns AP. The selection transistor STR may include a gate electrode or a portion of the word line WL, first and second impurity regions IM1 and IM2 disposed on opposite sides of the active pattern AP, and a gate insulation layer Gₒₓ between the gate electrode and the active pattern AP. The first and second impurity regions IM1 and IM2 may be doped with impurities (or dopants) of a second conductivity type opposite to the first conductivity type. The word line WL may run in the first direction X1 across a plurality of active patterns AP.

The active patterns AP and the first device isolation pattern 20 may be covered with a first upper insulation layer 12. The first upper insulation layer 12 may have a single-layered or multi-layered structure of at least one selected from, for example, silicon oxide, silicon nitride, silicon oxynitride, and SiOCH. First and second contact plugs CT1 and CT2 may penetrate the first upper insulation layer 12 to contact the first and second impurity regions IM1 and IM2, respectively.

A separation line pattern IP may penetrate the first upper insulation layer 12, the first device isolation pattern 20, and the plate lines PL of the cell stack ST, thereby being adjacent to the first substrate 100. The separation line pattern IP may have a single-layered or multi-layered structure of at least one selected from silicon oxide, silicon nitride, and silicon oxynitride. When viewed in plan, the separation line pattern IP may have a linear shape that extends in the first direction X1. The separation line pattern IP may separate from each other the plate lines PL located at the same level. The separation line pattern IP may penetrate a portion of the stack insulation layer 5 positioned at a lowermost portion of the cell stack ST, thereby being spaced apart from the first substrate 100. Alternatively, the separation line pattern IP may penetrate an entirety of the stack insulation layer 5 positioned at a lowermost portion of the cell stack ST, thereby being in contact with the first substrate 100.

Connection lines CL may be positioned on the first upper insulation layer 12. The connection lines CL may be covered with a second upper insulation layer 14. Third contact plugs CT3 may penetrate the second upper insulation layer 14 to contact corresponding first contact plugs CT1.

An electrode plug CEP may penetrate the first upper insulation layer 12, the first device isolation pattern 20, and the cell stack ST, thereby being adjacent to the first substrate 100. One electrode plug CEP may be connected through the connection line CL and the second contact plug CT2 to the second impurity region IM2 of one selection transistor STR.

A dielectric layer FL may be interposed between the electrode plug CEP and the plate lines PL of the cell stack ST. When viewed in plan, the dielectric layer FL may surround the electrode plug CEP. The plate lines PL may surround the electrode plug CEP. Thus, the capacitor FCA may increase in capacitance. The dielectric layer FL may extend to intervene between the electrode plug CEP and the stack insulation layer 5 of the cell stack ST. The dielectric layer FL may extend to intervene between the electrode plug CEP and the first device isolation pattern 20 and between the electrode plug CEP and the first upper insulation layer 12. The dielectric layer FL may extend to intervene the first substrate 100 and a bottom surface of the electrode plug CEP. The electrode plug CEP may have a first vertical length H1.

The dielectric layer FL may have a single-layered or multi-layered structure of at least one selected from a ferroelectric material and an antiferroelectric material. The ferroelectric material may be at least one selected from HfO₂, ZrO₂, HfₓZr₁₋ₓO₂, BaTiO₃, SrTiO₃, and SrₓBa₁₋ₓTiO₃, and the antiferroelectric material may be at least one selected from ZrO₂, Hf_{y}Zr_{1-y}O₂, PbZrO₃, and AgNbO₃, where x may be equal to or greater than 0.5 and y may be less than 0.5.

The first insulation layer 1 of the stack insulation layer 5 may be in contact with a sidewall of the dielectric layer FL. The second insulation layer 3 of the stack insulation layer 5 may be spaced apart from the dielectric layer FL.

One capacitor FCA may be constituted by a portion of the electrode plug CEP, a portion of the plate line PL adjacent to the electrode plug CEP, and the dielectric layer FL between the portion of the electrode plug CEP and the portion of the plate line PL. In the one capacitor FCA, the portion of the electrode plug CEP may correspond to the first electrode E1 of FIG. 1. In the one capacitor FCA, the portion of the plate line PL may correspond to the second electrode E2 of FIG. 1. The capacitor FCA may be a ferroelectric capacitor. FIG. 3B discloses a structure (one string structure) where a plurality of capacitors FCA are connected in series to the second impurity region IM2 of one selection transistor STR. The electrode plug CEP may be a common electrode or a common plate of the plurality of capacitors FCA.

In FIGS. 2 and 3A, based on the separation line pattern IP positioned at a center of the cell structure CS, a structure on the left side may be mirror-symmetric to a structure on the right side.

On the connection region CNR, the plate lines PL of the cell stack ST may have their end portions that are offset from each other and form a stepwise structure. The first device isolation 20 and the first upper insulation layer 12 may have their sidewalls aligned with that of a third plate line PL(3) or an uppermost one of the plate lines PL. An end portion of the cell stack ST may be covered with a planarized insulation layer 40. The planarized insulation layer 40 may have a single-layered or multi-layered structure of at least one selected from silicon oxide, silicon nitride, silicon oxynitride, and SiOCH. The second upper insulation layer 14 may extend to cover the planarized insulation layer 40.

On the connection region CNR, first plate connection contact plugs CCT may penetrate the second upper insulation layer 14 to contact corresponding end portions of the plate lines PL, respectively. The plate connection contact plugs CCT may include metal, such as tungsten, aluminum, copper, titanium, or tantalum.

The bit lines BL may be disposed on the second upper insulation layer 14. The bit lines BL may extend in the second direction X2 and may be spaced apart from each other in the first direction X1. The bit line BL may be connected to the first impurity region IM1 through the third contact plug CT3 and the first contact plug CT1. The bit lines BL may include metal, such as aluminum, tungsten, or copper.

The bit lines BL may be covered with a third upper insulation layer 16. The third upper insulation layer 16 may have a single-layered or multi-layered structure of at least one selected from silicon oxide, silicon nitride, silicon oxynitride, SiOCH, and SiCN.

Referring to FIGS. 3A and 3B, the peripheral circuit structure PS may include a second substrate 200, a second device isolation pattern 30, an inner dielectric pattern 38, peripheral circuit transistors PTR, peripheral lines IT, and input/output pads IOP. The second substrate 200 may be a semiconductor substrate. A rear surface 200_B of the second substrate 200 may be closer to the cell structure CS than a front surface 200_F of the second substrate 200. The rear surface 200_B of the second substrate 200 may be covered with a backside insulation layer 36. The backside insulation layer 36 may have a single-layered or multi-layered structure of at least one selected from silicon oxide, silicon nitride, and SiCN. The backside insulation layer 36 may be in contact with the third upper insulation layer 16 of the cell structure CS. The peripheral circuit structure PS and the cell structure CS may be boned by a dielectric-to-dielectric fashion.

The second substrate 200 may be provided with the second device isolation pattern 30 to limit active regions for the peripheral circuit transistors PTR. The peripheral circuit transistors PTR may be disposed on the front surface 200_F of the second substrate 200. The front surface 200_F of the second substrate 200 and the peripheral circuit transistors PTR may be sequentially covered with a first front insulation layer 32 and a second front insulation layer 34. The first front insulation layer 32 and the second front insulation layer 34 may each have a single-layered or multi-layered structure of at least one selected from silicon oxide, silicon nitride, silicon oxynitride, SiOCN, and SiCN. The peripheral lines IT may be positioned in (or between) the first front insulation layer 32 and the second front insulation layer 34. The input/output pads IOP may be positioned on the second front insulation layer 34. The peripheral circuit transistors PTR may be connected to the peripheral lines IT and the input/output pads IOP. The inner dielectric pattern 38 may be positioned in the second substrate 200 and in contact with a bottom surface of one of the second device isolation patterns 30.

The peripheral circuit transistors PTR and the peripheral lines IT may constitute the peripheral circuits (the sub-word line driver SWD, the sense amplifier S/A, the row decoder, the column decoder, and the control logic) discussed with reference to FIG. 1. The bit-line connection contact plug BLC may penetrate the backside insulation layer 36, the inner dielectric pattern 38, the second device isolation pattern 30, and the first front insulation layer 32 of the peripheral circuit structure PS, and may also penetrate the third upper insulation layer 16 of the cell structure CS to connect one of the bit lines BL to one of the peripheral lines IT. The bit-line connection contact plug BLC may have a second vertical length H2. The second vertical length H2 may be less than the first vertical length H1. Thus, a signal transmission distance between the bit line BL and the peripheral circuit transistor PTR may be reduced to improve an operating speed of the semiconductor memory device.

Second plate connection contact plugs PLC may penetrate the backside insulation layer 36, the inner dielectric pattern 38, the second device isolation pattern 30, and the first front insulation layer 32 of the peripheral circuit structure PS, and may also penetrate the third upper insulation layer 16 of the cell structure CS to come into connection with corresponding first plate connection contact plugs CCT. Each of the second plate connection contact plugs PLC may have a vertical length the same as a sum of the second vertical length H2 and the thickness of the bit line BL. The sum of the second vertical length H2 and the thickness of the bit line BL may be less than the first vertical length H1.

In FIGS. 2, 3A, and 3B, the word-line connection contact plug WLC of FIG. 1 is not depicted, but a word-line connection contact plug may be formed to connect an end portion of the word line WL to the peripheral circuit structure PS. A vertical length of the word-line connection contact plug WLC may be less than the first vertical length H1.

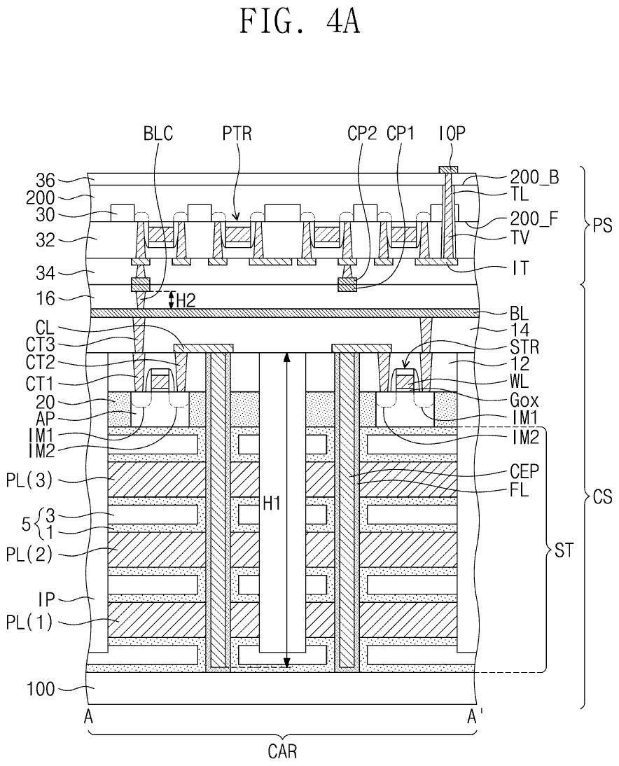

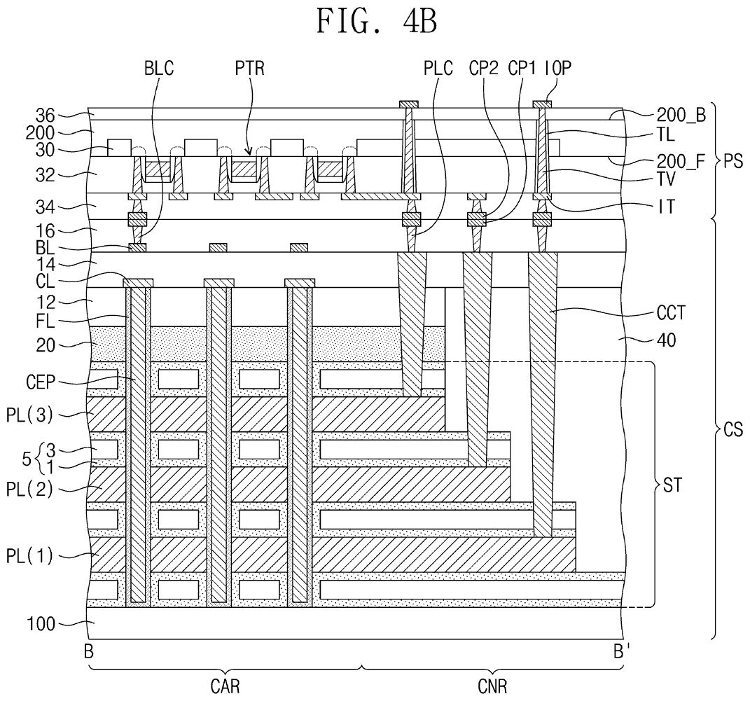

FIG. 4A illustrates a cross-sectional view taken along line A-A′ of FIG. 2. FIG. 4B illustrates a cross-sectional view taken along line B-B′ of FIG. 2.

Referring to FIGS. 4A and 4B, in a semiconductor memory device according to the present embodiment, the cell structure CS and the peripheral circuit structure PS may be bonded by a hybrid copper bonding (HCB) fashion. For example, the cell structure CS may include bit-line connection contact plugs BLC, second plate connection contact plugs PLC, and first connection pads CP1 that are disposed in the third upper insulation layer 16. The first connection pads CP1 may be disposed on a top end of the third upper insulation layer 16. The bit-line connection contact plugs BLC and the second plate connection contact plugs PLC may penetrate the third upper insulation layer 16 to come into connection with the first connection pads CP1. The bit-line connection contact plugs BLC may have a second vertical length H2, and the second plate connection contact plugs PLC may have a vertical length the same as a sum of the second vertical length H2 and the thickness of the bit line BL. The second vertical length H2 may be less than a first vertical length H1 of the electrode plug CEP. The sum of the second vertical length H2 and the thickness of the bit line BL may be less than the first vertical length H1 of the electrode plug CEP.

In the present embodiment, the peripheral circuit structure PS may have a structure similar to an inverted structure of the peripheral circuit structure PS depicted in FIGS. 3A and 3B. In the peripheral circuit structure PS according to the present embodiment, the front surface 200_F of the second substrate 200 may be closer to the cell structure CS than the rear surface 200_B of the second substrate 200. The first front insulation layer 32 and the second front insulation layer 34 may be positioned between the second substrate 200 and the cell structure CS. The second front insulation layer 34 may be in contact with the third upper insulation layer 16. Second connection pads CP2 may be disposed on a bottom end of the second front insulation layer 34. The second connection pads CP2 may be correspondingly in contact with the first connection pads CP1. The second connection pads CP2 and the first connection pads CP1 may be formed of, for example, copper. The first connection pad CP1 and the second connection pad CP2 that are in contact with each other may be merged to have an invisible interface therebetween.

The rear surface 200_B of the second substrate 200 may be covered with a backside insulation layer 36. The input/output pads IOP may be positioned on the backside insulation layer 36. A through via TV may penetrate the first front insulation layer 32, the second device isolation pattern 30, the second substrate 200, and the backside insulation layer 36, thereby connecting the peripheral line IT to the input/output pad IOP. A via insulation layer TL may surround a sidewall of the through via TV. Other configurations may be identical or similar to those discussed with reference to FIGS. 2, 3A, and 3B.

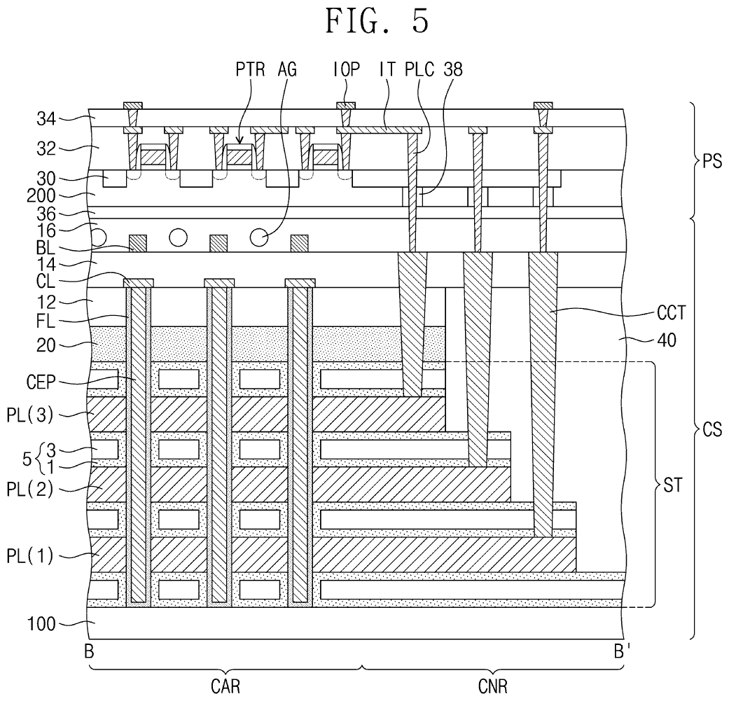

FIG. 5 illustrates a cross-sectional view taken along line B-B′ of FIG. 2.

Referring to FIG. 5, in a semiconductor memory device according to the present embodiment, an air gap AG may be present between the bit lines BL. The third upper insulation layer 16 may include a plurality of air gaps AG. Other configurations may be identical or similar to those discussed with reference to FIGS. 3A and 3B. In the semiconductor memory device according to the present embodiment, as the bit lines BL are disposed on the cell stack ST, the air gaps AG may be easily formed between the bit lines BL. Thus, a parasitic capacitance between the bit lines BL may be reduced to decrease interference or noise. As a result, the semiconductor memory device may have improved reliability.

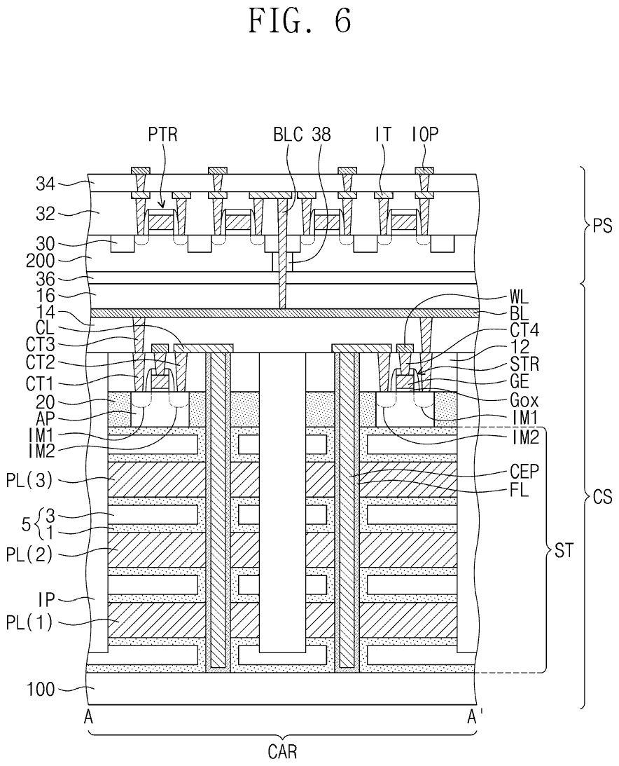

FIG. 6 illustrates a cross-sectional view taken along line B-B′ of FIG. 2.

Referring to FIG. 6, in a semiconductor memory device according to the present embodiment, the selection transistor STR may include a gate electrode GE. The gate electrode GE may not be a portion of the word line WL. A first upper insulation layer 12 may cover the gate electrode GE. A fourth contact plug CT4 may penetrate the first upper insulation layer 12 to contact the gate electrode GE. A word line WL may be disposed on the first upper insulation layer 12. The word line WL may be covered with a second upper insulation layer 14. The word line WL may be located at the same level as that of the connection line CL. A plurality of gate electrodes GE may be connected through the fourth contact plugs CT4 to a single word line WL. Other configurations may be identical or similar to those discussed with reference to FIGS. 3A and 3B.

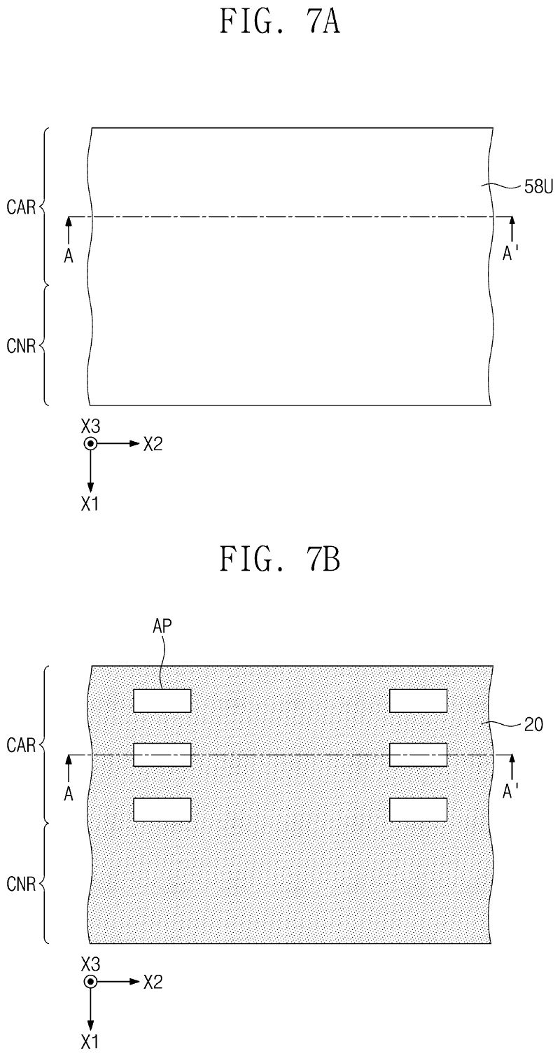

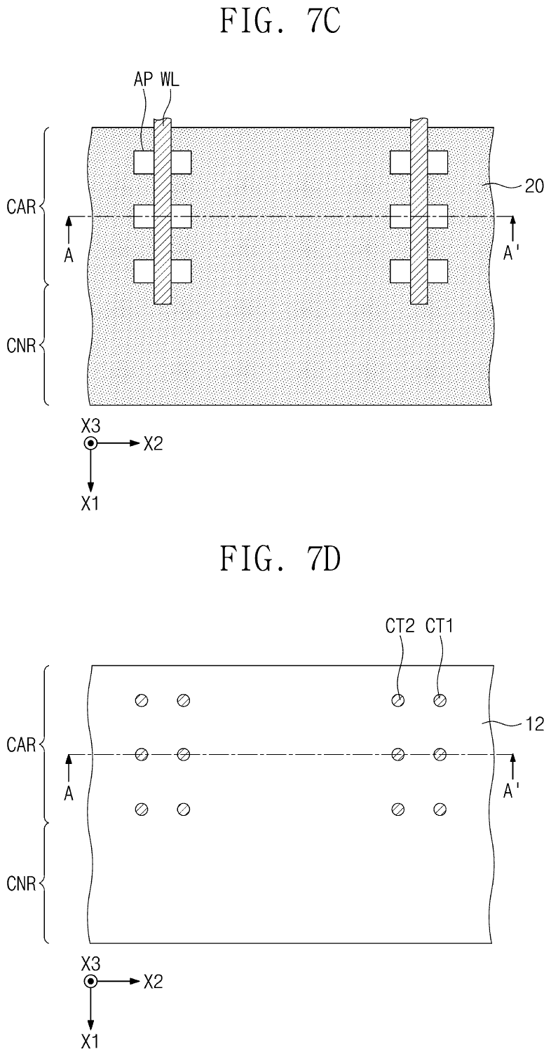

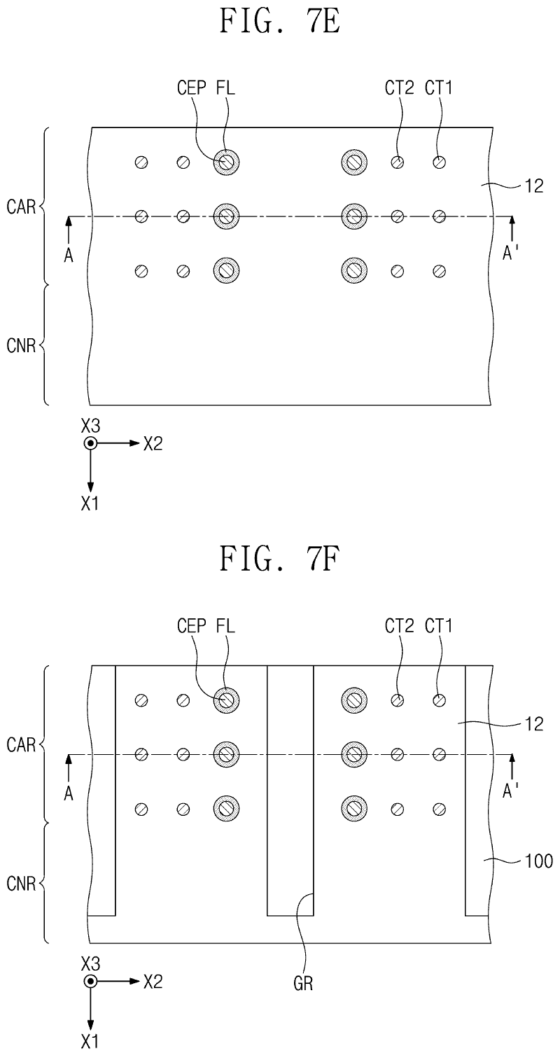

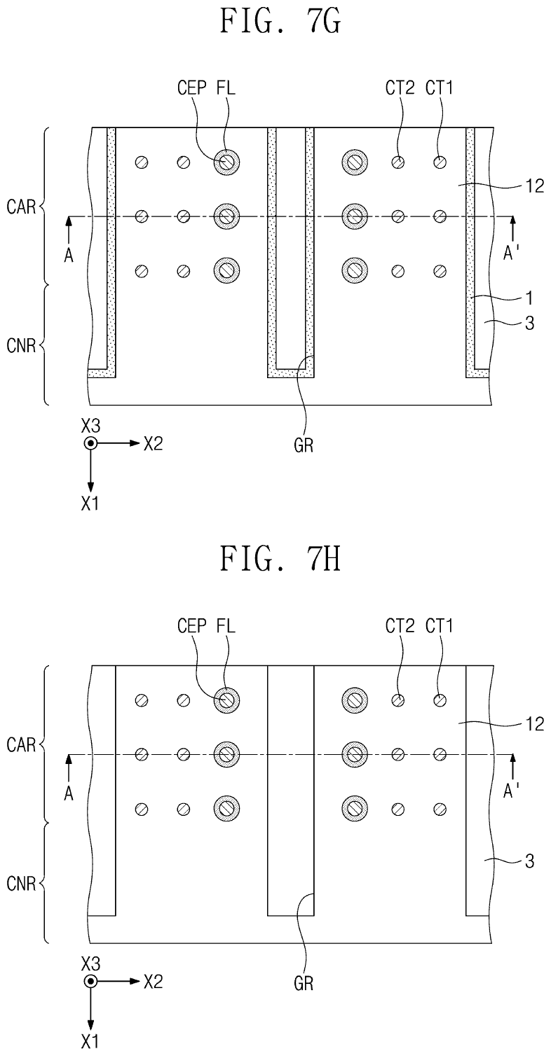

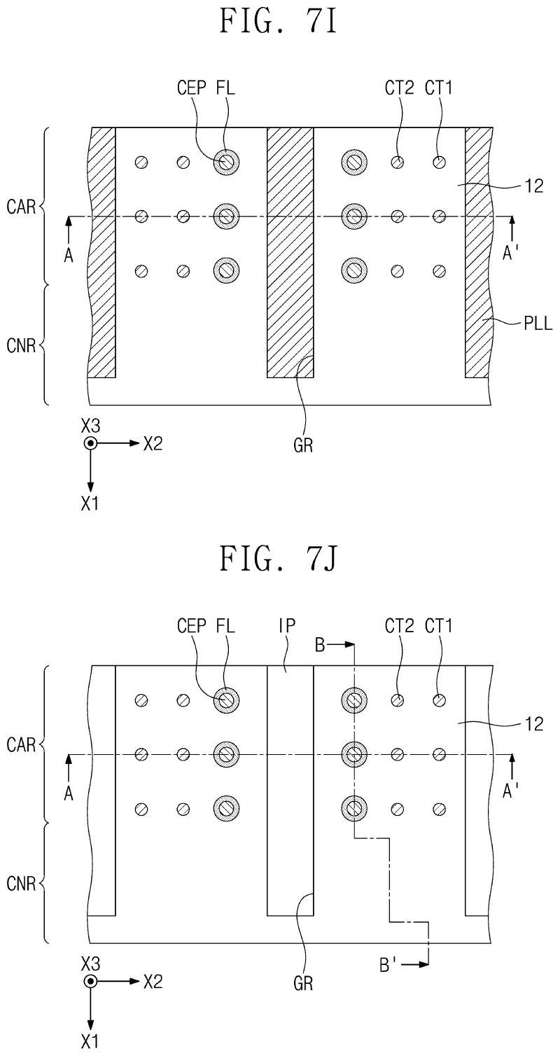

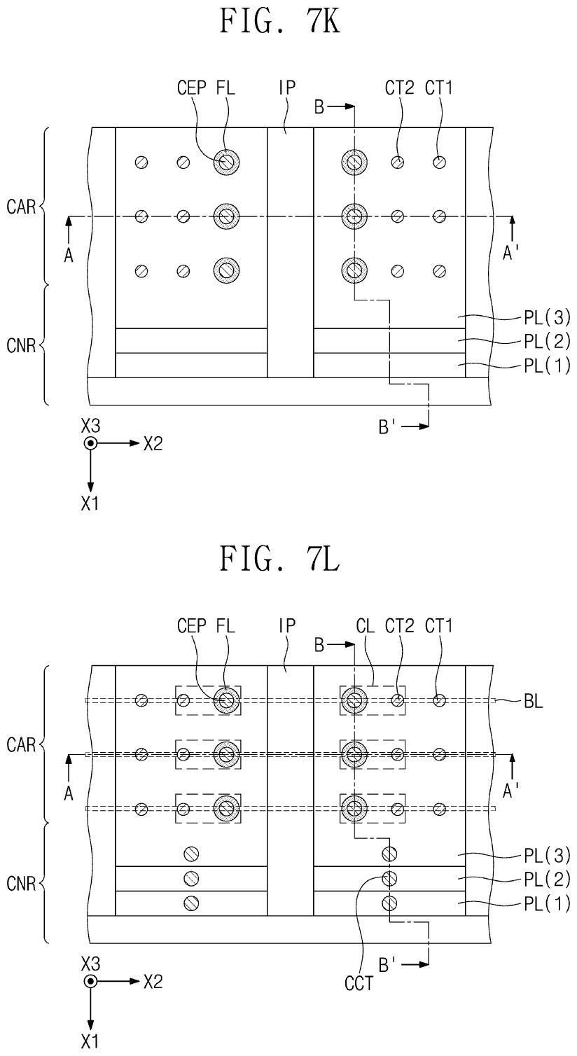

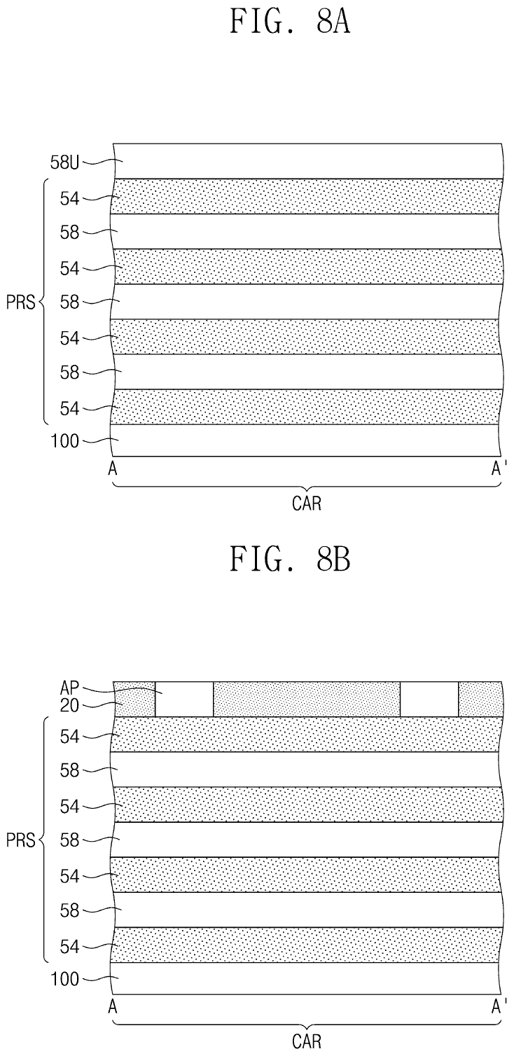

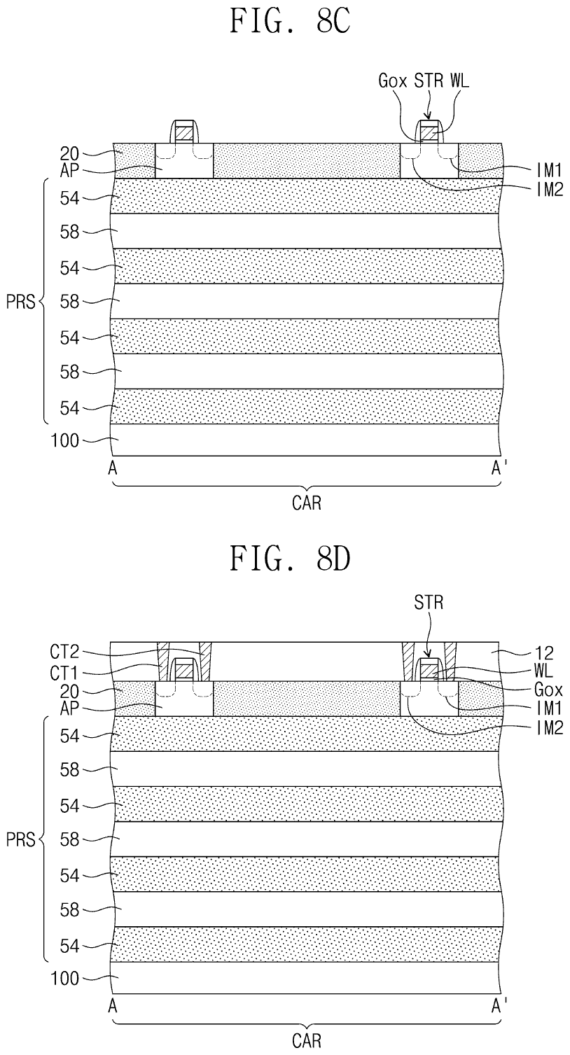

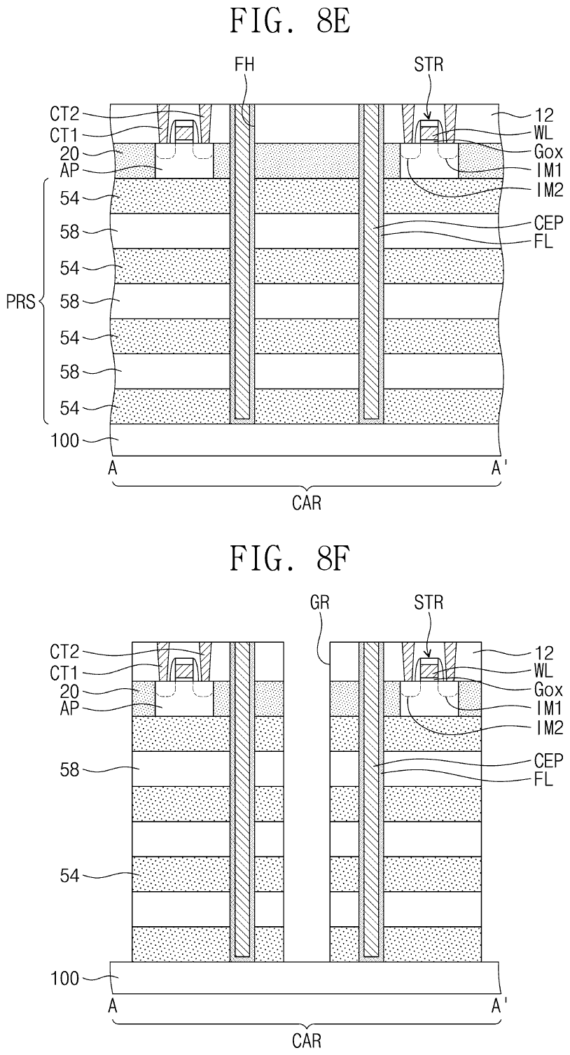

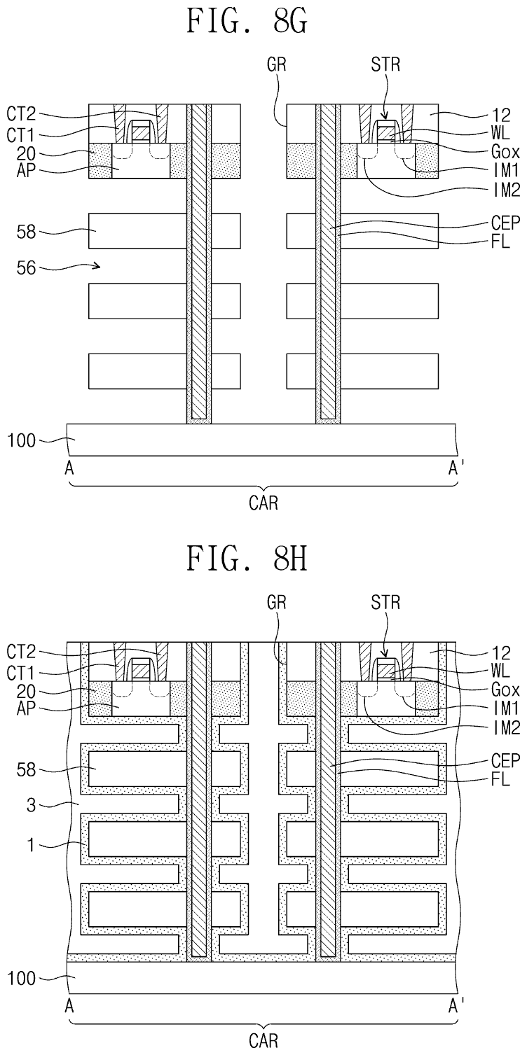

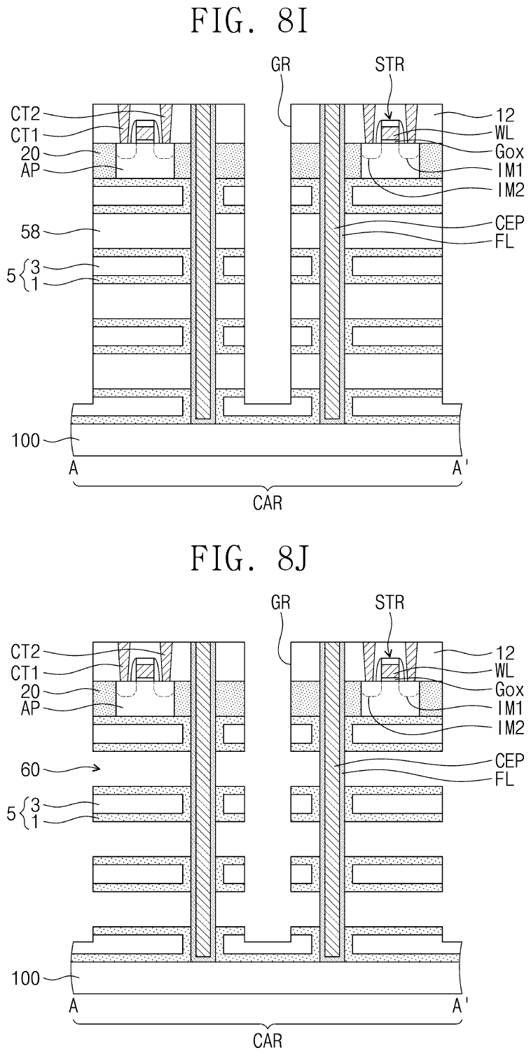

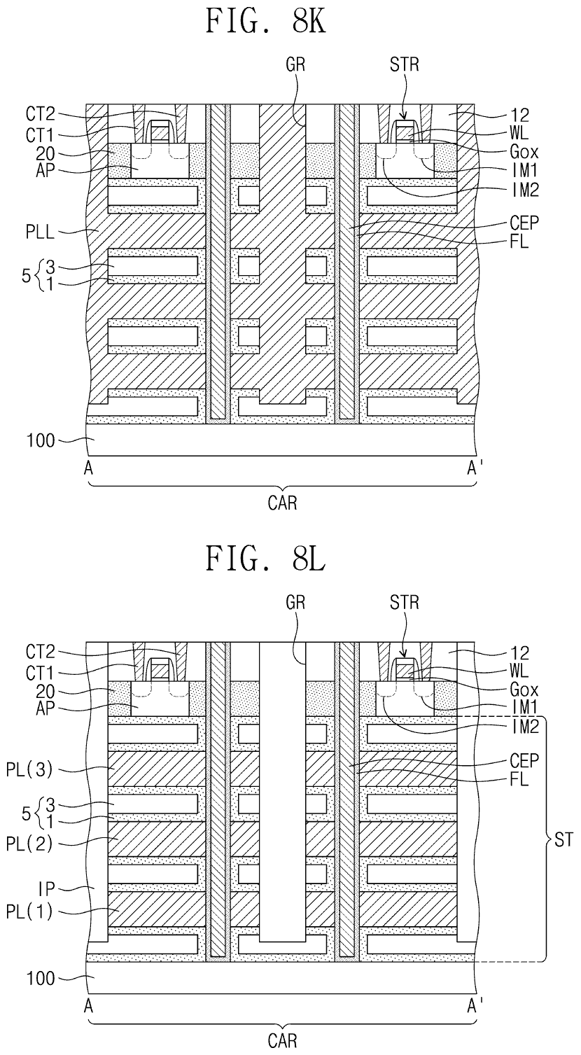

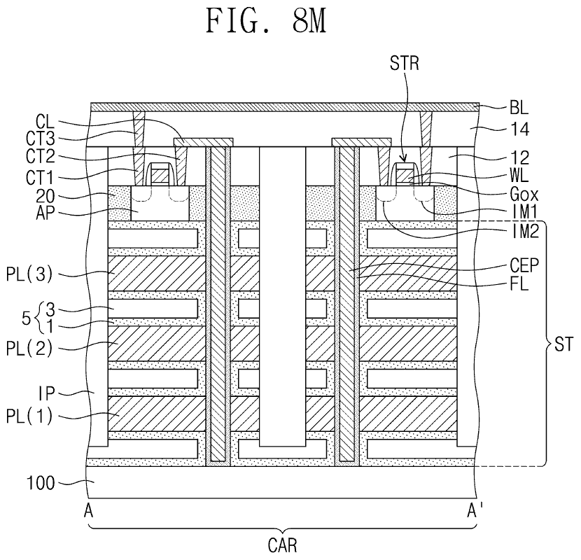

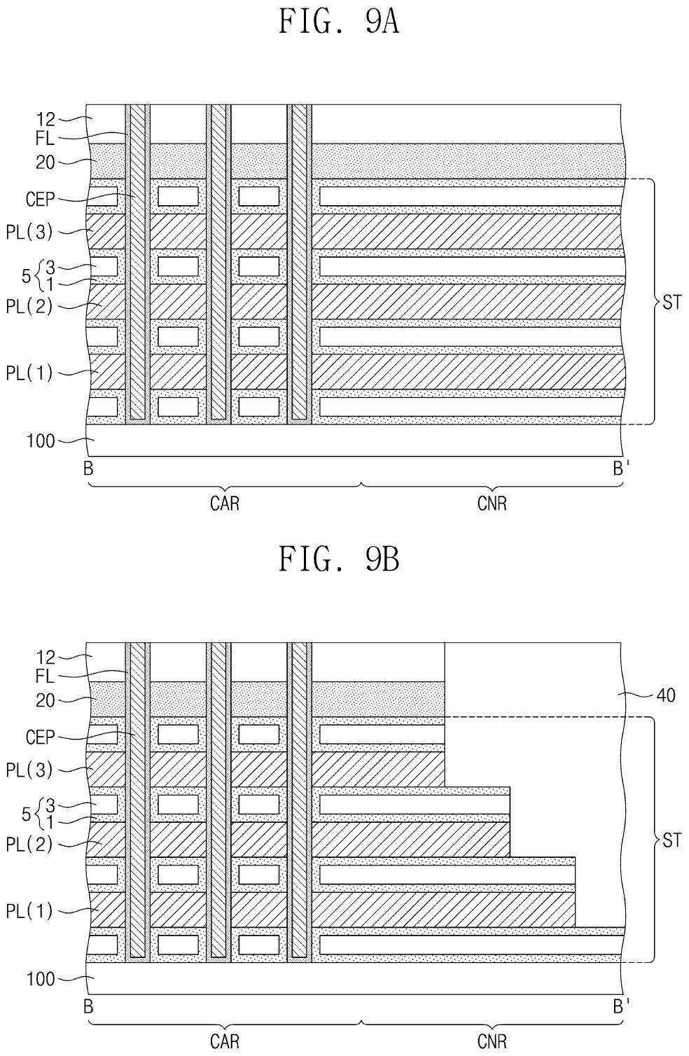

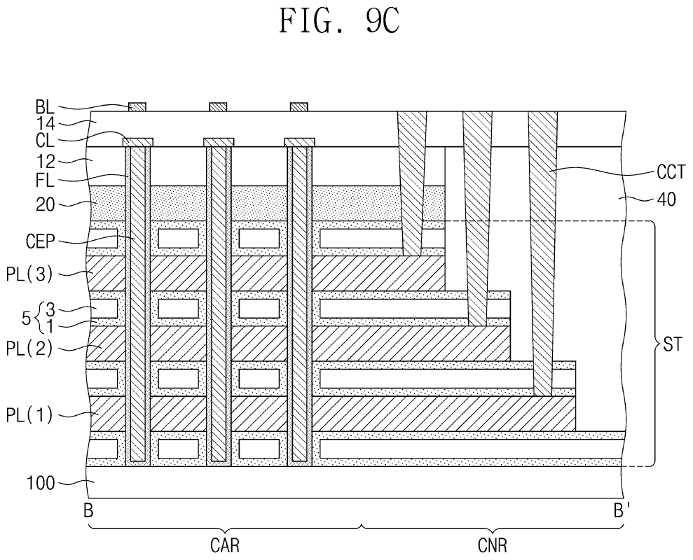

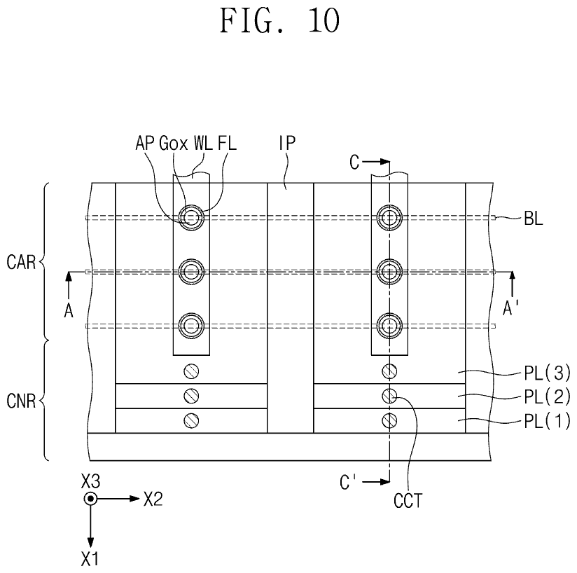

FIGS. 7A to 7L illustrate plan views showing a method of fabricating a semiconductor memory device whose plan view is depicted in FIG. 2. FIGS. 8A to 8M illustrate cross-sectional views showing a method of fabricating a semiconductor memory device whose cross-section is depicted in FIG. 3A. FIGS. 9A to 9C illustrate cross-sectional views showing a method of fabricating a semiconductor memory device whose cross-section is depicted in FIG. 3B.

FIG. 8A may correspond to a cross-section taken along line A-A′ of FIG. 7A. Referring to FIGS. 7A and 8A, first sacrificial layers 54 and second sacrificial layers 58 may be alternately and repeatedly stacked on a first substrate 100. The first substrate 100 may include a cell array region CAR and a connection region CNR that are arranged side by side along a first direction X1. The first substrate 100 may be formed of, for example, single-crystalline silicon. The first sacrificial layers 54 may be formed of, for example, germanium, silicon-germanium, or carbon-doped silicon-germanium (SiGe:C). The second sacrificial layers 58 may be formed of single-crystalline silicon. The first sacrificial layers 54 and the second sacrificial layers 58 may be formed by a selective epitaxial growth (SEG) process. The first sacrificial layers 54 and the second sacrificial layers 58 may constitute a preliminary stack PRS. A semiconductor layer 58U may be formed on the preliminary stack PRS. The semiconductor layer 58U may be formed of the same material (e.g., single-crystalline silicon) as that of the second sacrificial layers 58.

FIG. 8B may correspond to a cross-section taken along line A-A′ of FIG. 7B. Referring to FIGS. 7A, 8A, 7B, and 8B, the semiconductor layer 58U may be etched to form active patterns AP and to expose a top surface of an uppermost first sacrificial layer 54 in the preliminary stack PRS. The active patterns AP may be disposed on the cell array region CAR, and may be two-dimensionally arranged along the first direction X1 and a second direction X2. After the formation of the active patterns AP, an insulation layer may be provided to cover the preliminary stack PRS, and an etch-back process or a chemical mechanical polishing (CMP) process may be performed to expose top surfaces of the active patterns AP and simultaneously to form a first device isolation pattern 20 that fills a space between the active patterns AP.

FIG. 8C may correspond to a cross-section taken along line A-A′ of FIG. 7C. Referring to FIGS. 7B, 8B, 7C, and 8C, a gate insulation layer Gₒₓ and word lines WL may be formed on the active patterns AP. And then, an ion implantation process may be performed to form first and second impurity regions IM1 and IM2 in the active patterns AP. Thus, selection transistors STR may be formed on the active patterns AP.

FIG. 8D may correspond to a cross-section taken along line A-A′ of FIG. 7D. Referring to FIGS. 7C, 8C, 7D, and 8D, a first upper insulation layer 12 may be formed to cover the selection transistors STR, the active patterns AP, and the first device isolation patterns 20. Contact holes may be formed in the first upper insulation layer 12, and may then be filled with a conductive material to form first and second contact plugs CT1 and CT2.

FIG. 8E may correspond to a cross-section taken along line A-A′ of FIG. 7E. Referring to FIGS. 7D, 8D, 7E, and 8E, the first upper insulation layer 12, the first device isolation pattern 20, and the preliminary stack PRS may be etched to form an electrode hole FH. The electrode hole FH may expose a top surface of the first substrate 100. A dielectric layer FL may be stacked on a front surface of the first upper insulation layer 12 to cover an inner sidewall and a bottom surface of the electrode hole FH. A conductive layer may be stacked on the dielectric layer FL to fill the electrode hole FH. In addition, the conductive layer and the dielectric layer FL may undergo a chemical mechanical polishing (CMP) process to expose a top surface of the first upper insulation layer 12 and top surfaces of the first and second contact plugs CT1 and CT2 and simultaneously to form an electrode plug CEP while leaving the dielectric layer FL in the electrode hole FH. The dielectric layer FL may be formed to have a single-layered or multi-layered structure of at least one selected from a ferroelectric material and an antiferroelectric material.

FIG. 8F may correspond to a cross-section taken along line A-A′ of FIG. 7F. Referring to FIGS. 7E, 8E, 7F, and 8F, the first upper insulation layer 12, the first device isolation pattern 20, and the preliminary stack PRS may be etched to form grooves GR that expose the top surface of the first substrate 100. When viewed in plan, the grooves GR may extend along the first direction X1. The grooves GR may be formed on both of the cell array region CAR and the connection region CNR.

The first sacrificial layers 54 may be replaced with stack insulation layers 5. For example, referring to FIGS. 7F, 8F, and 8G, the first sacrificial layers 54 may be removed through the grooves GR. Thus, first empty spaces 56 may be formed between the second sacrificial layers 58. The first empty spaces 56 may expose a sidewall of the dielectric layer FL. An uppermost one of the first empty spaces 56 may expose a bottom surface of the active pattern AP and a bottom surface of the first device isolation pattern 20. A lowermost one of the first empty spaces 56 may expose the top surface of the first substrate 100.

FIG. 8H may correspond to a cross-section taken along line A-A′ of FIG. 7G. Referring to FIGS. 7G, 8G, and 8H, a first insulation layer 1 and a second insulation layer 3 may be sequentially formed on the first upper insulation layer 12. The first insulation layer 1 may cover a sidewall of the groove GR, lateral surfaces of the dielectric layer FL, and top, lateral, and bottom surfaces of the second sacrificial layers 58 exposed to the first empty spaces 56. The second insulation layer 3 may fill the grooves GR and the first empty space 56. The first insulation layer 1 and the second insulation layer 3 may undergo an etch-back process or a CMP process to remove the first insulation layer 1 and the second insulation layer 3 on the first upper insulation layer 12 and to expose the top surface of the first upper insulation layer 12.

FIG. 8I may correspond to a cross-section taken along line A-A′ of FIG. 7H. Referring to FIGS. 7G, 8H, 7H, and 8I, an etching process may be performed such that most of the first and second insulation layers 1 and 3 in the groove GR may be removed to expose sidewalls of the second sacrificial layers 58 and to form the stack insulation layers 5. Each of the stack insulation layers 5 may include the first insulation layer 1 and the second insulation layer 3. A lowermost stack insulation layer 5 may not be removed, but may remain to cover the top surface of the first substrate 100. Additionally, the active patterns AP may not be exposed, but may be covered with the first device isolation pattern 20 and the stack insulation layer 5, thereby being protected in the etching process.

The second sacrificial layers 58 may be replaced with plate lines PL. For example, referring to FIGS. 7H, 8I, and 8J, the second sacrificial layers 58 may be removed through the groove GR, and thus second empty spaces 60 may be formed. The second empty spaces 60 may expose top and bottom surfaces of the stack insulation layers 5 and also to expose the sidewall of the dielectric layer FL.

FIG. 8K may correspond to a cross-section taken along line A-A′ of FIG. 7I. Referring to FIGS. 7H, 8I, 7I, and 8K, a plate layer PLL may be stacked on the first upper insulation layer 12 to fill the groove GR and the second empty spaces 60. The plate layer PLL may include metal, such as tungsten. The plate layer PLL may undergo a CMP process to remove the plate layer PLL on the first upper insulation layer 12 and to expose the top surface of the first upper insulation layer 12. FIG. 8L may correspond to a cross-section taken along line A-A′ of FIG. 7J. FIG. 9A may correspond to a cross-section taken along line B-B′ of FIG. 7J. Referring to FIGS. 7I, 8K, 7J, 8L, and 9A, the plate layer PLL in the groove GR may be removed to expose sidewalls of the stack insulation layers 5, a sidewall of the first device isolation pattern 20, and a sidewall of the first upper insulation layer 12 and simultaneously to form the plate lines PL in the second empty spaces 60. Thus, a cell stack ST may be formed which includes the plate lines PL and the stack insulation layers 5 that are alternately and stacked. And then, the groove GR may be filled with a dielectric material to form a separation line pattern IP. The plate lines PL, the stack insulation layers 5, the first device isolation pattern 20, and the first upper insulation layer 12 may be positioned not only on the cell array region CAR but also on the connection region CNR.

FIG. 9B may correspond to a cross-section taken along line B-B′ of FIG. 7K. A cross-section taken along line A-A′ of FIG. 7K may be the same as FIG. 8L. Referring to FIGS. 7J, 8L, 9A, 7K, and 9B, trimming processes and etching processes may be alternately and repeatedly performed such that the first upper insulation layer 12, the first device isolation pattern 20, and the cell stack ST on the connection region CNR may be etched to allow the cell stack ST to have a stepwise end portion. Therefore, end portions of the plate lines PL may be offset from each other on the connection region CNR. A planarized insulation layer 40 may be formed to cover the end portion of the cell stack ST. The planarized insulation layer 40 may be formed to have a single-layered or multi-layered structure of at least one selected from silicon oxide, silicon nitride, silicon oxynitride, and SiOCH. The planarized insulation layer 40 may be formed to have a top surface coplanar with that of the first upper insulation layer 12.

FIG. 8M may correspond to a cross-section taken along line A-A′ of FIG. 7L. FIG. 9C may correspond to a cross-section taken along line B-B′ of FIG. 7L. Referring to FIGS. 7K, 8L, 9B, 7L, 8M, and 9C, connection lines CL may be formed on the first upper insulation layer 12. The connection line CL may connect the second contact plug CT2 to the electrode plug CEP. A second upper insulation layer 14 may be formed to cover the first upper insulation layer 12 and the connection lines CL. A third contact plug CT3 in contact with the first contact plug CT1 may be formed in the second upper insulation layer 14. On the connection region CNR, first plate connection contact plugs CCT may be formed to contact corresponding end portions of the plate lines PL. Bit lines BL may be formed on the second upper insulation layer 14. The bit lines BL may be in contact with the third contact plugs CT3. The bit lines BL may be formed to extend in the second direction X2 and to be spaced apart from each other in the first direction X1.

Subsequently, referring to FIGS. 2, 3A, and 3B, a third upper insulation layer 16 may be formed to cover the bit lines BL. As a result, a cell structure CS may be manufactured.

A backside insulation layer 36 may be formed to reside on a rear surface of a second substrate 200 and to contact the third upper insulation layer 16, and then a thermocompression process may be performed to bond the second substrate 200 to the cell structure CS. A typical procedure may be executed to form peripheral circuit transistors PTR and a first front insulation layer 32 on a front surface of the second substrate 200. Bit-line connection contact plugs BLC and second plate connection contact plugs PLC may be formed to penetrate the first front insulation layer 32 and the second substrate 200. Peripheral lines IT, a second front insulation layer 34, and input/output pads IOP may be formed on the first front insulation layer 32. As a result, a peripheral circuit structure PS may be manufactured.

In a method of fabricating a semiconductor memory device according to the present inventive concepts, as a selective epitaxial growth (SEG) process may be used to form the first and second sacrificial layers 54 and 58, the active pattern AP may be formed of single-crystalline silicon. It may thus be possible to manufacture the selection transistor STR with improved performance. In addition, the first sacrificial layers 54 may be replaced with the stack insulation layers 5, and the second sacrificial layers 58 may be replaced with the plate lines PL. Thus, the selection transistors STR may be formed on the cell stack ST. In such a case, a reduced connection distance may be provided between the selection transistors STR and the peripheral circuit structure PS. Moreover, the air gap AG may be easily formed between the bit lines BL.

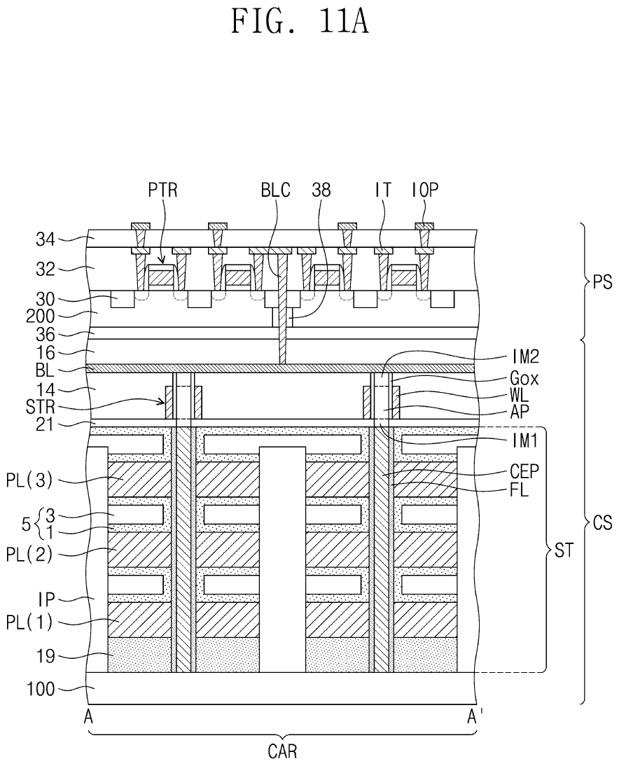

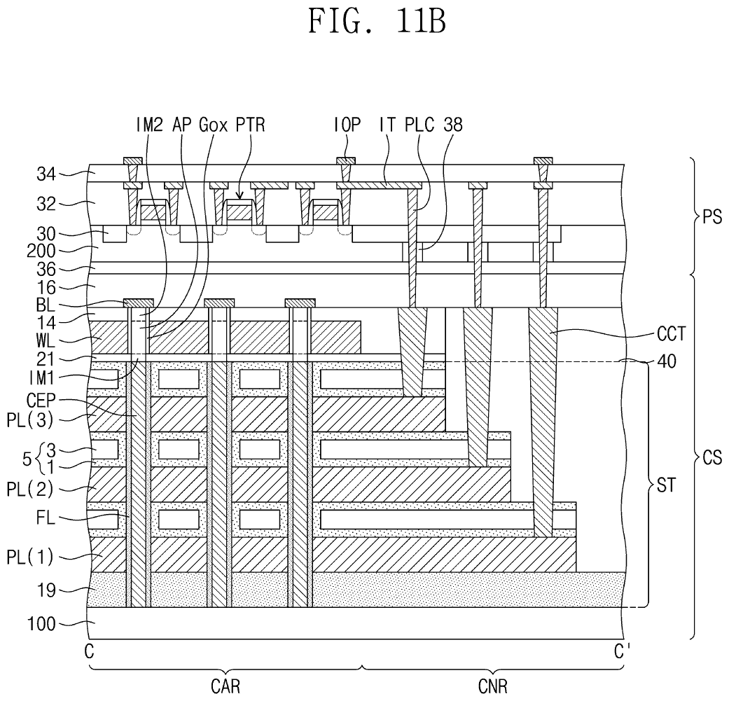

FIG. 10 illustrates a plan view showing a semiconductor memory device according to some embodiments of the present inventive concepts. FIG. 11A illustrates a cross-sectional view taken along line A-A′ of FIG. 10. FIG. 11B illustrates a cross-sectional view taken along line C-C′ of FIG. 10.

Referring to FIGS. 10, 11A, and 11B, in a semiconductor memory device according to the present embodiment, a cell stack ST may include a first cover insulation layer 19, and may also include plate lines PL and stack insulation layers 5 that are alternately and repeatedly stacked on the first cover insulation layer 19. Each of the stack insulation layers 5 may include a first insulation layer 1 and a second insulation layer 3. The first insulation layer 1 may surround the second insulation layer 3. A structure of the first cover insulation layer 19 may be different from those of the stack insulation layers 5. The first cover insulation layer 19 may have a single-layered structure of one of silicon oxide, silicon nitride, and silicon oxynitride. The first cover insulation layer 19 may be in contact with a first substrate 100.

A separation line pattern IP may extend upwards from a top surface of the first substrate 100 to penetrate at least a portion of the cell stack ST. The separation line pattern IP may penetrate all of the plate lines PL. The separation line pattern IP may be inserted into the stack insulation layer 5 at top of the cell stack ST.

An electrode plug CEP may penetrate the cell stack ST to contact the first substrate 100. A dielectric layer FL may be interposed between the electrode plug CEP and the cell stack ST. The cell stack ST may be covered with a second cover insulation layer 21. The second cover insulation layer 21 may have a single-layered or multi-layered structure of at least one selected from silicon oxide, silicon nitride, and silicon oxynitride.

An active pattern AP may penetrate the second cover insulation layer 21 to contact the electrode plug CEP. The active pattern AP may have a circular shape when viewed in plan. A portion of the active pattern AP may outwardly protrude from the second cover insulation layer 21. The active pattern AP may be provided therein with a first impurity region IM1 and a second impurity region IM2 that are vertically spaced apart from each other. The first impurity region IM1 may be positioned on a lower portion of the active pattern AP to contact the electrode plug CEP. The second impurity region IM2 may be positioned on an upper portion of the active pattern AP.

A sidewall of the active pattern AP may be covered with a gate insulation layer Gₒₓ. A word line WL may cover the gate insulation layer Gₒₓ. The word line WL may have a gate-all-around shape that surrounds the active pattern AP and extends in the first direction X1. A top end of the word line WL may be lower than that of the active pattern AP. A selection transistor STR according to the present embodiment may have a vertical channel.

A second upper insulation layer 14 may cover a sidewall of the word line WL and a top surface of the second cover insulation layer 21. A top surface of the second upper insulation layer 14 may be located at the same level as that of a top surface of the active pattern AP.

Bit lines BL may be disposed on the second upper insulation layer 14. The bit lines BL may extend in the second direction X2, while being in contact the second impurity regions IM2 on top ends of the active patterns AP. The bit lines BL and the second upper insulation layer 14 may be covered with a third upper insulation layer 16. A peripheral circuit structure PS may be bonded onto a cell structure CS configured discussed above. The peripheral circuit structure PS may have a structure the same as that discussed with reference to FIGS. 3A and 3B.

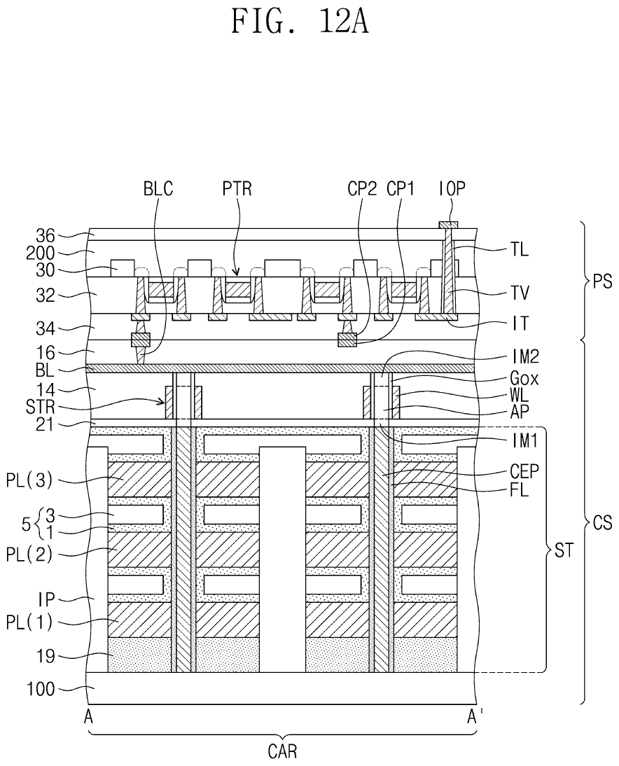

FIG. 12A illustrates a cross-sectional view taken along line A-A′ of FIG. 10. FIG. 12B illustrates a cross-sectional view taken along line C-C′ of FIG. 10.

A semiconductor memory device of FIGS. 12A and 12B may have a structure in which a structure of the semiconductor memory device of FIGS. 11A and 11B is combined with a structure of the semiconductor memory device of FIGS. 4A and 4B. For example, the selection transistor STR of the cell structure CS may have a vertical channel as shown in FIGS. 11A and 11B. The cell structure CS according to the present embodiment may include bit-line connection contact plugs BLC, second plate connection contact plugs PLC, and first connection pads CP1 disposed in the third upper insulation layer 16. The peripheral circuit structure PS according to the present embodiment may have a structure the same as or similar to that of the peripheral circuit structure PS depicted in FIGS. 4A and 4B. The peripheral circuit structure PS according to the present embodiment may include second connection pads CP2 disposed on a bottom end of the second front insulation layer 34. The second connection pads CP2 may be correspondingly in contact with the first connection pads CP1.

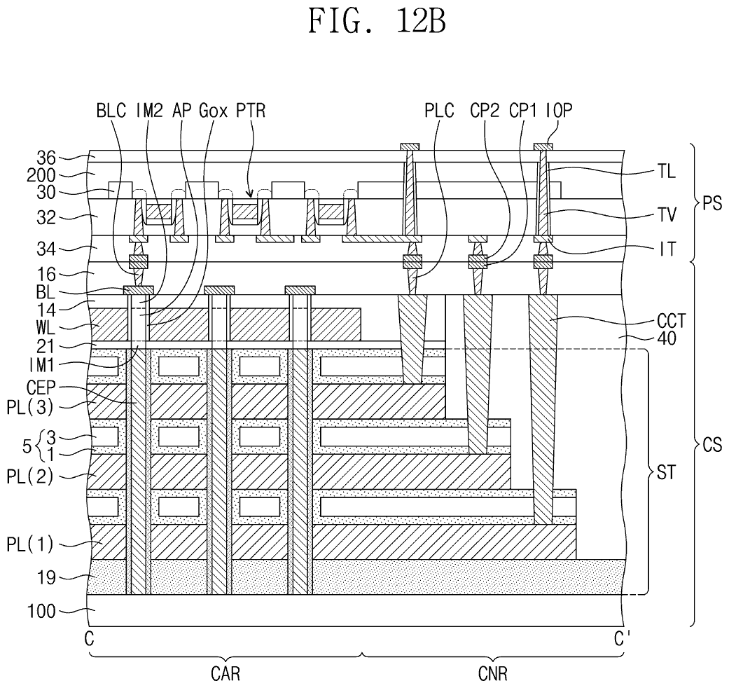

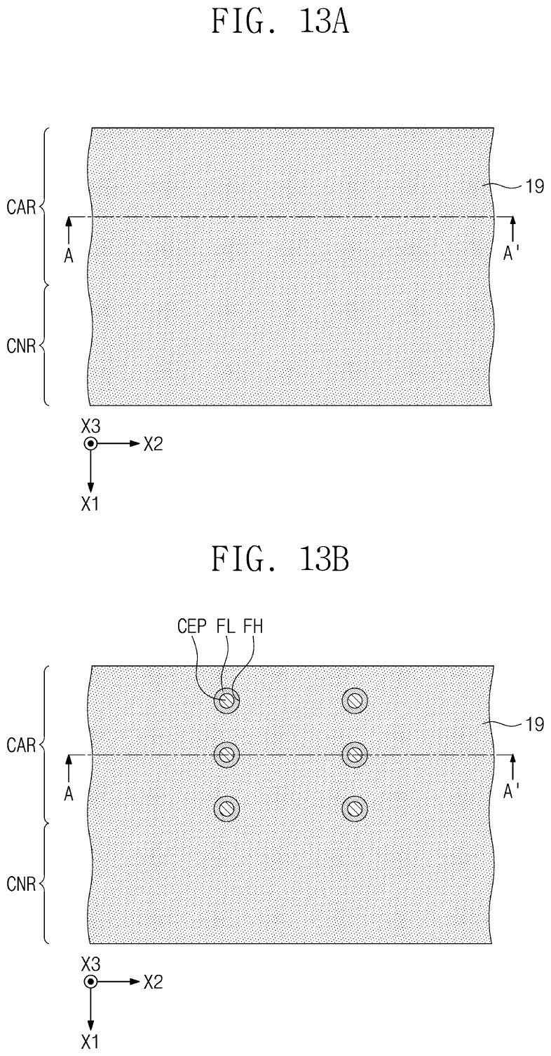

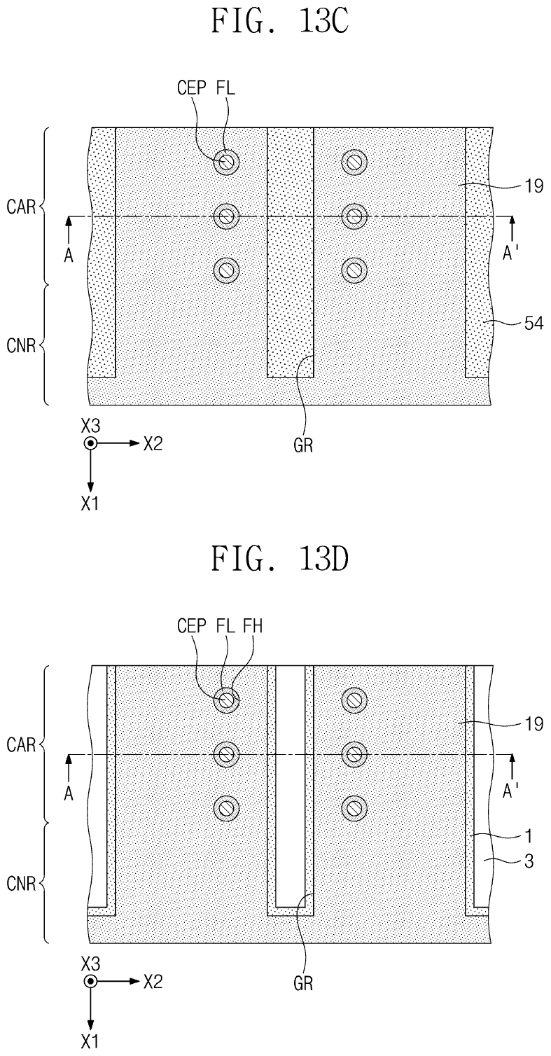

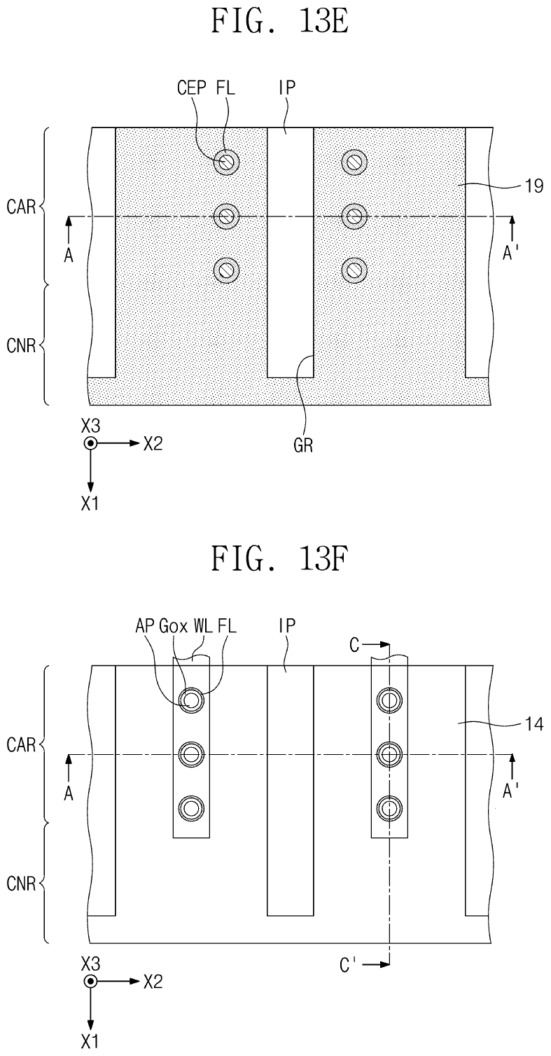

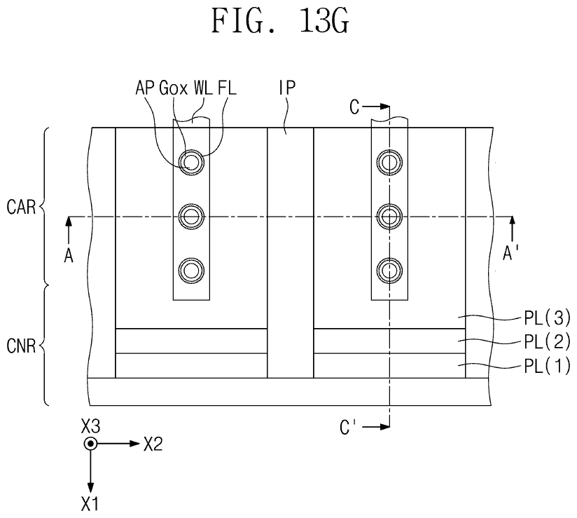

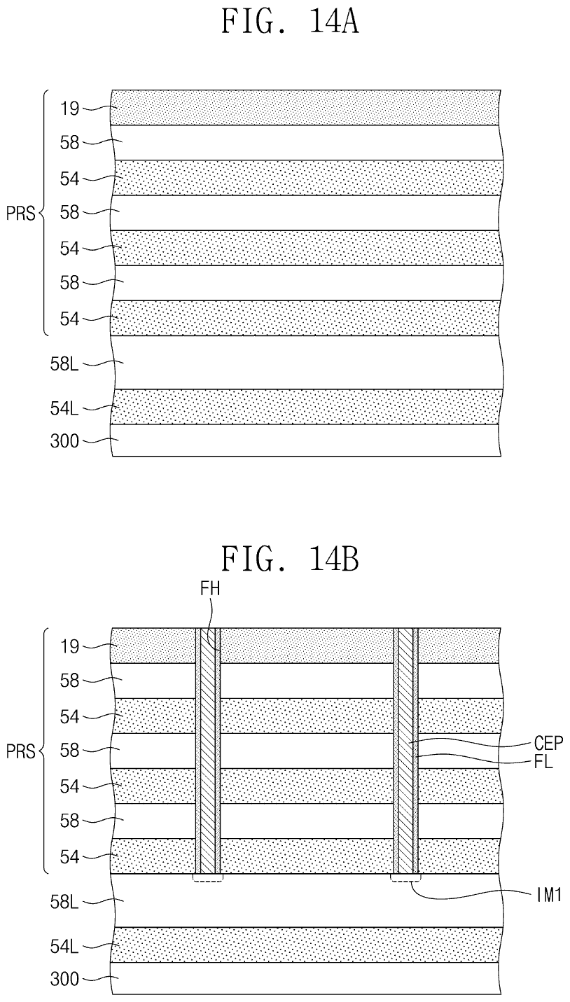

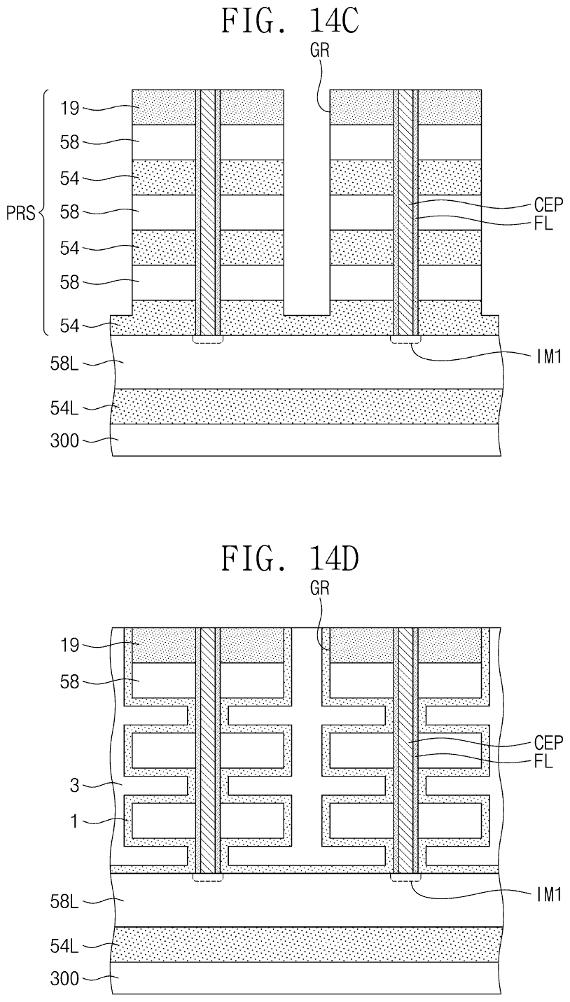

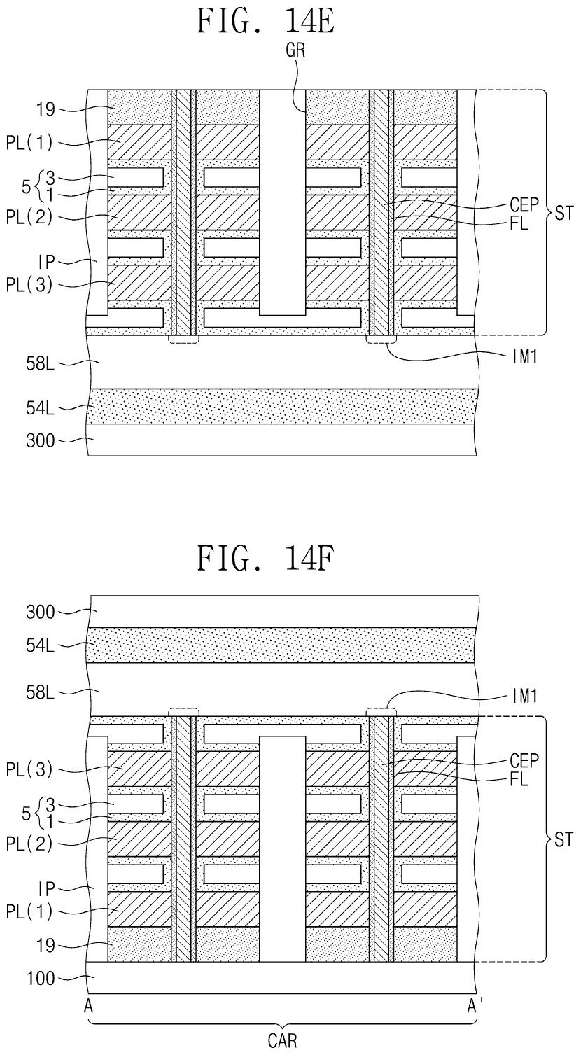

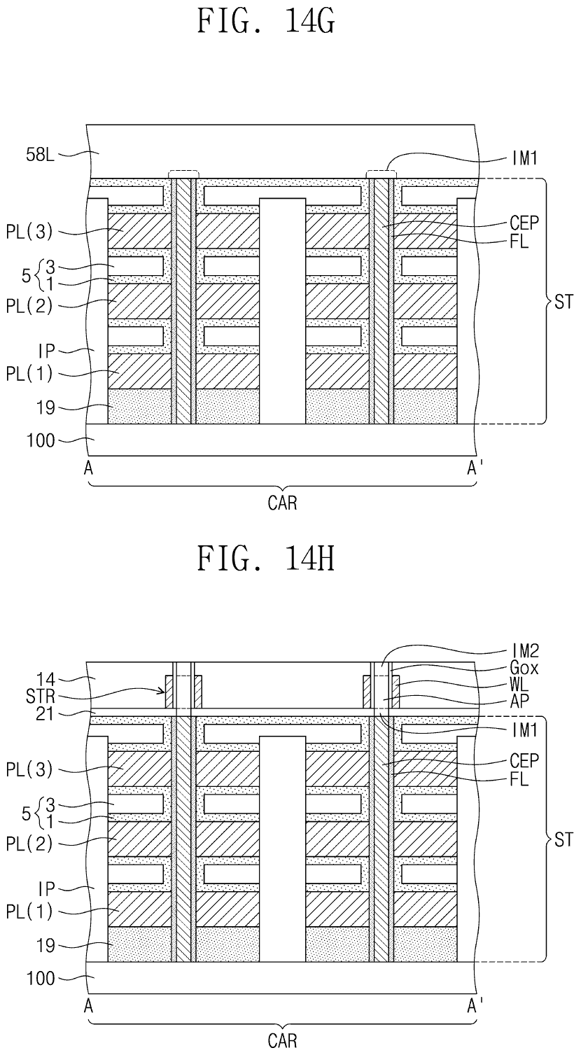

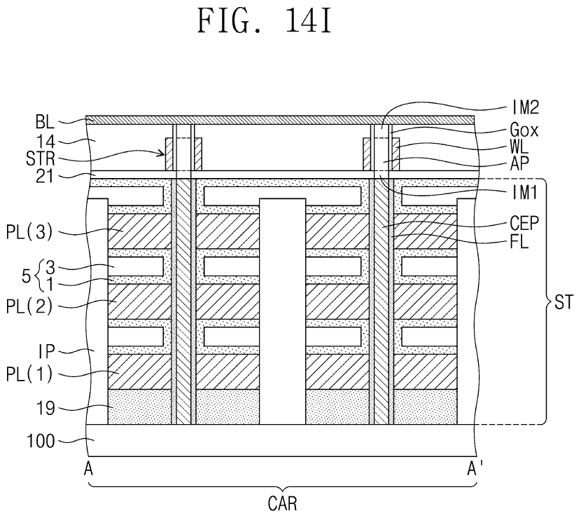

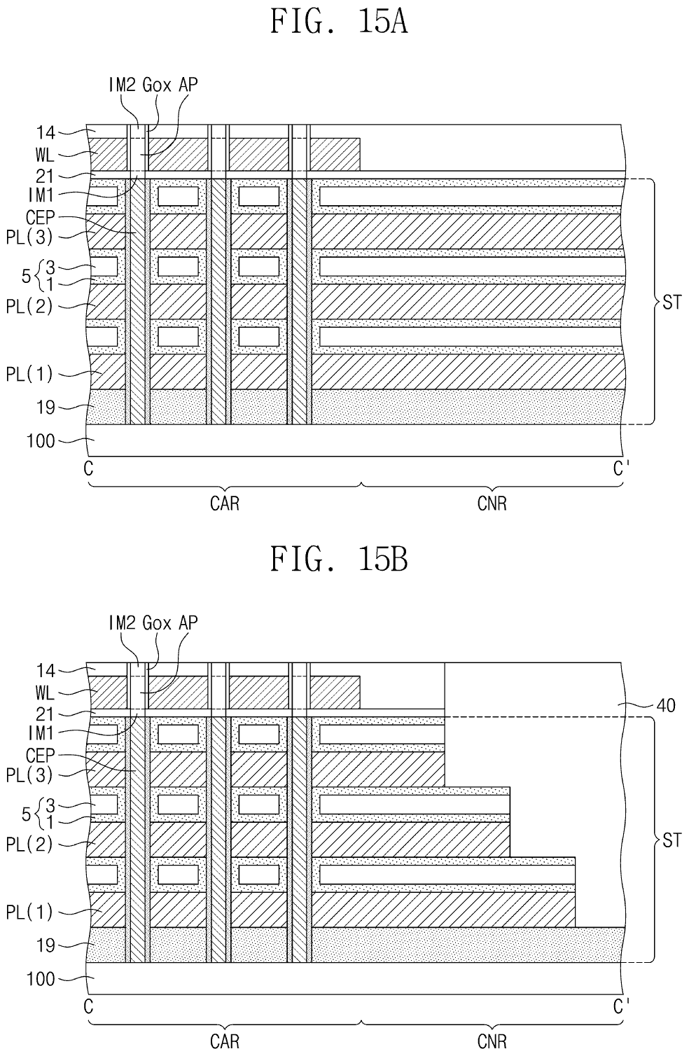

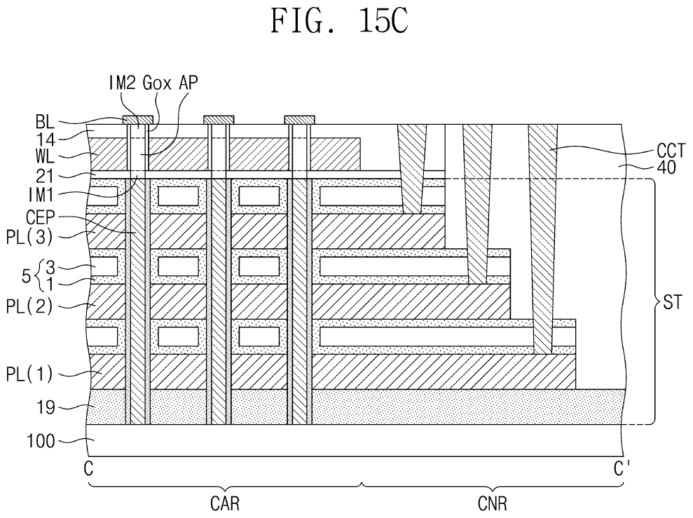

FIGS. 13A to 13G illustrate plan views showing a method of fabricating a semiconductor memory device whose plan view is depicted in FIG. 10. FIGS. 14A to 14I illustrate cross-sectional views showing a method of fabricating a semiconductor memory device whose cross-section is depicted in FIG. 11A. FIGS. 15A to 15C illustrate cross-sectional views showing a method of fabricating a semiconductor memory device whose cross-section is depicted in FIG. 11B.

FIG. 14A may correspond to a cross-section taken along line A-A′ of FIG. 13A. Referring to FIGS. 13A and 14A, a first semiconductor layer 54L and a second semiconductor layer 58L may be sequentially stacked on a sacrificial substrate 300. The sacrificial substrate 300 may be formed of, for example, single-crystalline silicon. The first semiconductor layer 54L may be formed of germanium, silicon-germanium, or carbon-doped silicon-germanium (SiGe:C). The second semiconductor layer 58L may be formed of single-crystalline silicon. The first semiconductor layer 54L and the second semiconductor layer 58L may be formed by a selective epitaxial growth (SEG) process.

First sacrificial layers 54 and second sacrificial layers 58 may be alternately and repeatedly stacked on the second semiconductor layer 58L. The first sacrificial layers 54 may be formed of, for example, germanium, silicon-germanium, or carbon-doped silicon-germanium (SiGe:C). The second sacrificial layers 58 may be formed of single-crystalline silicon. The first sacrificial layers 54 and the second sacrificial layers 58 may be formed by a selective epitaxial growth (SEG) process. A first cover insulation layer 19 may be formed on an uppermost one of the second sacrificial layers 58. The first sacrificial layers 54, the second sacrificial layers 58, and the first cover insulation layer 19 may constitute a preliminary stack PRS.

FIG. 14B may correspond to a cross-section taken along line A-A′ of FIG. 13B. Referring to FIGS. 13B and 14B, the preliminary stack PRS may be etched to form an electrode hole FH. The electrode hole FH may expose a top surface of the second semiconductor layer 58L. An ion implantation process may be executed to form a first impurity region IM1 on the second semiconductor layer 58L on a floor of the electrode hole FH. A dielectric layer FL may be stacked on the preliminary stack PRS to cover an inner sidewall and a bottom surface of the electrode hole FH. The dielectric layer FL may undergo an anisotropic etching process to remove the dielectric layer FL on the bottom surface of the electrode hole FH and to expose the first impurity region IM1. A conductive layer may be stacked on the preliminary stack PRS to fill the electrode hole FH. The conductive layer may undergo a CMP process to expose a top surface of the preliminary stack PRS and simultaneously to form an electrode plug CEP in the electrode hole FH.

FIG. 14C may correspond to a cross-section taken along line A-A′ of FIG. 13C. Referring to FIGS. 13B, 14b, 13C, and 14C, the preliminary stack PRS may be etched to form grooves GR. When viewed in plan, the grooves GR may extend along the first direction X1. The grooves GR may be formed on both of the cell array region CAR and the connection region CNR. The grooves GR may expose a lowermost first sacrificial layer 54 of the preliminary stack PRS.

The first sacrificial layers 54 may be replaced with stack insulation layers 5. FIG. 14D may correspond to a cross-section taken along line A-A′ of FIG. 13D. Referring to FIGS. 13C, 14C, 13D, and 14D, the first sacrificial layers 54 may be removed through the grooves GR, and the second sacrificial layers 58 may be exposed through the grooves GR. A first insulation layer 1 and a second insulation layer 3 may be sequentially formed on the preliminary stack PRS. The first insulation layer 1 may cover a sidewall of the groove GR, lateral surfaces of the dielectric layer FL, and top, lateral, and bottom surfaces of the second sacrificial layers 58. The first insulation layer 1 and the second insulation layer 3 may undergo an etch-back process or a CMP process to remove the first insulation layer 1 and the second insulation layer 3 on the preliminary stack PRS and to expose a top surface of the preliminary stack PRS.

The second sacrificial layers 58 may be replaced with plate lines PL. FIG. 14E may correspond to a cross-section taken along line A-A′ of FIG. 13E. Referring to FIGS. 13G, 14D, 13E, and 14E, an etching process may be performed such that most of the first and second insulation layers 1 and 3 in the groove GR may be removed to expose sidewalls of the second sacrificial layers 58 and to form stack insulation layers 5. Each of the stack insulation layers 5 may include the first insulation layer 1 and the second insulation layer 3. At this stage, a lowermost stack insulation layer 5 may not be removed, but may remain to cover a top surface of the second semiconductor layer 58L.

The second sacrificial layers 58 may be removed through the groove GR to expose top and bottom surfaces of the stack insulation layers 5 and a sidewall of the dielectric layer FL. A plate layer may be stacked on the preliminary stack PRS to fill a space between the groove GR and the stack insulation layers 5. The plate layer in the groove GR may be removed to form plate lines PL. Therefore, a cell stack ST may be formed which includes the plate lines PL, the stack insulation layers 5 that are alternately stacked with the plate lines PL, and the first cover insulation layer 19.

Referring to FIGS. 14E and 14F, the first substrate 100 may be bonded onto the first cover insulation layer 19 of the cell stack ST. And then, a structure of FIG. 14E may be turned upside down to allow the sacrificial substrate 300 to locate on top side.

Referring to FIGS. 14F and 14G, the sacrificial substrate 300 and the first semiconductor layer 54L may be removed to expose a top surface of the second semiconductor layer 58L.

FIG. 14H illustrates a cross-sectional view taken along line A-A′ of FIG. 13F. FIG. 15A illustrates a cross-sectional view taken along line C-C′ of FIG. 13F. Referring to FIGS. 14G, 13F, 14H, and 15A, the second semiconductor layer 58L may be etched to form active patterns AP. The active patterns AP may be formed to overlap the electrode plugs CEP. There may be exposed the stack insulation layer 5 of the cell stack ST on sides of the active patterns AP. A second cover insulation layer 21 may be formed on the cell stack ST. A gate insulation layer Gₒₓ may be formed on sidewalls of the active patterns AP. A word line WL may be formed which covers a sidewall of the gate insulation layer Gₒₓ. A second upper insulation layer 14 may be formed on the second cover insulation layer 21. An ion implantation process may be executed to form second impurity regions IM2 on top ends of the active patterns AP.

The plate lines PL, the stack insulation layers 5, the first device isolation pattern 20, and the first upper insulation layer 12 may be positioned not only on the cell array region CAR but also on the connection region CNR.

FIG. 15B may correspond to a cross-section taken along line C-C′ of FIG. 13G. A cross-section taken along line A-A′ of FIG. 13G may be the same as FIG. 14H. Referring to FIGS. 13F, 14H, 15A, 13G, and 15B, trimming processes and etching processes may be alternately and repeatedly performed such that the second upper insulation layer 14, the second cover insulation layer 21, and the cell stack ST on the connection region CNR may be etched to allow the cell stack ST to have a stepwise end portion. Therefore, end portions of the plate lines PL may be offset from each other on the connection region CNR. A planarized insulation layer 40 may be formed to cover the end portion of the cell stack ST. The planarized insulation layer 40 may be formed to have a top surface coplanar with that of the second upper insulation layer 14.

Referring to FIGS. 14I and 15C, on the connection region CNR, first plate connection contact plugs CCT may be formed to contact corresponding end portions of the plate lines PL. Bit lines BL may be formed on the second upper insulation layer 14. The bit lines BL may be in contact with the second impurity regions IM2 of the active patterns AP. The bit lines BL may be formed to extend in the second direction X2 and to be spaced apart from each other in the first direction X1. Subsequently, a third upper insulation layer 16 may be formed on the second upper insulation layer 14. And then, a peripheral circuit structure PS may be formed as discussed with reference to FIGS. 3A and 3B.

In a cell structure of a semiconductor memory device according to the present inventive concepts, bit lines and selection transistors may be positioned adjacent to a peripheral circuit structure, and thus a reduced electrical pathway may be provided between the peripheral circuit structure and the selection transistors, which may result in an improvement in operating speed.

In a method of fabricating a semiconductor memory device according to the present inventive concepts, a selective epitaxial growth (SEG) process may be used to form first and second sacrificial layers, and thus an active pattern may be formed of single-crystalline silicon. Thus, a selection transistor with improved performance may be manufactured on a cell stack. In addition, first sacrificial layers may be replaced with stack insulation layers, and second sacrificial layers may be replaced with plate lines. Thus, the selection transistors may be formed on the cell stack. Accordingly, a reduced connection distance may be provided between the selection transistors and the peripheral circuit structure.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. The embodiments of FIGS. 1 to 6 and 10 to 12B may be combined with each other.

What is claimed is:

1. A semiconductor memory device, comprising:
a first substrate;
a cell stack on the first substrate, wherein the cell stack comprises a plurality of plate lines and a plurality of stack insulation layers that are alternately stacked;
an electrode plug that penetrates the cell stack;
a dielectric layer between the electrode plug and the cell stack;
a selection transistor on the cell stack and connected to the electrode plug;
an upper insulation layer that covers the selection transistor and the cell stack; and
a peripheral circuit structure on the upper insulation layer and connected to the selection transistor.

2. The semiconductor memory device of claim 1, further comprising:
a bit line covered with the upper insulation layer and connected to the selection transistor; and
a bit-line connection contact plug that penetrates the upper insulation layer to connect the bit line to the peripheral circuit structure,
wherein a vertical length of the bit-line connection contact plug is less than a vertical length of the electrode plug.

3. The semiconductor memory device of claim 2, wherein
the bit line is provided in plural, and
the upper insulation layer comprises an air gap between the plurality of bit lines.

4. The semiconductor memory device of claim 1, wherein the stack insulation layer comprises:
a first insulation layer in contact with the plate lines; and
a second insulation layer spaced apart from the plate lines,
wherein the first insulation layer comprises a material different from a material of the second insulation layer.

5. The semiconductor memory device of claim 4, wherein
the first insulation layer extends to contact a sidewall of the dielectric layer, and
the second insulation layer is spaced apart from the dielectric layer.

6. The semiconductor memory device of claim 1, further comprising:
an active pattern on the cell stack and covered with the upper insulation layer; and
a device isolation pattern in contact with a lateral surface of the active pattern,
wherein a gate insulation layer of the selection transistor is on the active pattern, and
wherein the electrode plug penetrates the device isolation pattern and is spaced apart from the active pattern.

7. The semiconductor memory device of claim 6, wherein the selection transistor comprises a gate electrode as a portion of a word line adjacent to a top surface of the active pattern,
wherein the word line does not overlap the electrode plug in a vertical direction along which the plurality of plate lines and the plurality of stack insulation layers are alternately stacked.

8. The semiconductor memory device of claim 1, further comprising:
an active pattern on the cell stack and in contact with the electrode plug;
a word line that surrounds a lateral surface of the active pattern and extends in a first direction parallel to a top surface of the first substrate;
a gate insulation layer between the word line and the active pattern; and
a bit line in contact with a top surface of the active pattern and intersecting the first direction,
wherein a portion of the word line and the active pattern constitute the selection transistor.

9. The semiconductor memory device of claim 1, wherein the first substrate comprises a cell array region and a connection region,
wherein an end portion of the cell stack constitutes a stepwise shape in the connection region.

10. The semiconductor memory device of claim 1, further comprising:
an input/output pad disposed on an exterior surface of the semiconductor memory device,
wherein the selection transistor is disposed between the cell stack and the exterior surface.

11. A semiconductor memory device, comprising:
a first substrate;
a cell stack on the first substrate, wherein the cell stack comprises a plurality of plate lines and a plurality of stack insulation layers that are alternately stacked;
a plurality of electrode plugs that penetrate the cell stack;
a plurality of dielectric layers between the electrode plugs and the cell stack;
a plurality of active patterns on the cell stack;
a plurality of word lines that are correspondingly adjacent to the active patterns and extend in a first direction parallel to a top surface of the first substrate;
a first upper insulation layer that covers the cell stack and the word lines;
a plurality of bit lines on the first upper insulation layer and intersecting the first direction;
a second upper insulation layer that covers the bit lines and the first upper insulation layer;
a second substrate on the second upper insulation layer;
a plurality of peripheral circuit transistors having gate structures disposed on one surface of the second substrate; and
a bit-line connection contact plug that connects one of the bit lines to one of the peripheral circuit transistors,
wherein a vertical length of the bit-line connection contact plug is less than a vertical length of one of the electrode plugs.

12. The semiconductor memory device of claim 11, wherein
the active patterns are correspondingly in contact with top surfaces of the electrode plugs, and
the word lines are correspondingly adjacent to sidewalls of the active patterns.

13. The semiconductor memory device of claim 11, wherein
the active patterns are correspondingly spaced apart from the electrode plugs, and
the word lines are correspondingly adjacent to top surfaces of the active patterns.

14. The semiconductor memory device of claim 13, further comprising a device isolation pattern that disposed in a space between the active patterns,
wherein the electrode plugs penetrate the device isolation pattern.

15. The semiconductor memory device of claim 11, wherein the second upper insulation layer comprises an air gap between the bit lines.

16. The semiconductor memory device of claim 11, wherein the stack insulation layer comprises:
a first insulation layer in contact with the plate lines; and
a second insulation layer spaced apart from the plate lines,
wherein the first insulation layer comprises a material different from a material of the second insulation layer.

17. The semiconductor memory device of claim 11, further comprising:
a lower insulation layer that covers a bottom surface of the second substrate and contacts the second upper insulation layer;
a first connection pad on a bottom end of the lower insulation layer; and
a second connection pad on a top end of the second upper insulation layer and in contact with the first connection pad.

18. A semiconductor memory device, comprising:
a first substrate having a cell array region and a connection region;
a cell stack on the first substrate, wherein the cell stack comprises a plurality of plate lines and a plurality of stack insulation layers that are alternately stacked, an end portion of the cell stack constituting a stepwise shape in the connection region;
a plurality of electrode plugs that penetrate the cell stack in the cell array region;
a plurality of dielectric layers between the electrode plugs and the cell stack;
a plurality of active patterns on the cell stack;
a plurality of selection transistors on the active patterns;
a plurality of word lines that are connected to gates of the selection transistors and extend in a first direction parallel to a top surface of the first substrate, respectively;
a first upper insulation layer that covers the cell stack and the word lines;
a plurality of bit lines on the first upper insulation layer and intersecting the first direction;
a planarized insulation layer that covers the end portion of the cell stack on the connection region;
a second upper insulation layer that covers the bit lines, the first upper insulation layer, and the planarized insulation layer;
a second substrate on the second upper insulation layer;
a plurality of peripheral circuit transistors on one surface of the second substrate;
a bit-line connection contact plug that connects one of the bit lines to one of the peripheral circuit transistors; and
a plurality of plate connection contact plugs in contact with the plate lines on the connection region, respectively.

19. The semiconductor memory device of claim 18, wherein a vertical length of the bit-line connection contact plug is less than a vertical length of the electrode plug.

20. The semiconductor memory device of claim 18, wherein the second upper insulation layer comprises an air gap between the bit lines.
